(19) United States
(12) Patent Application Publication
(10) Pub. No.: US 2024/0032305 A1
(43) Pub. Date: Jan. 25, 2024

(54) MEMORY CELL AND METHODS FOR PROCESSING A MEMORY CAPACITOR

(71) Applicant: Ferroelectric Memory GmbH, Dresden (DE)

(72) Inventors: Alireza KASHIR, Dresden (DE); Tony SCHENK, Dresden (DE); Stefan Ferdinand MÜLLER, Radebeul (DE)

(21) Appl. No.: 17/814,745

(22) Filed: Jul. 25, 2022

(51) Int. Cl. H01L 27/11514

(52) U.S. Cl. CPC H01L 27/11514

(57) ABSTRACT

Various aspects relate to a memory cell including: a first electrode; a second electrode; and a memory element, the first electrode, the second electrode, and the memory element forming a memory capacitor; wherein the memory element includes a spontaneously polarizable layer stack which includes an alternating sequence of first sublayers and second sublayers, wherein each of the second sublayers substantially consists of a mixed material of an oxide of a first transition metal and an oxide of a second transition metal, wherein each of the first sublayers substantially consists of the oxide of the first transition metal or second transition metal; wherein a first concentration of the first transition metal and a second concentration of the second transition metal in the mixed material are substantially different from one another, and/or wherein the alternating sequence starts with one of the first sublayers and ends with another one of the first sublayers.

### TECHNICAL FIELD

Various aspects of this disclosure relate to a memory cell and methods for processing a memory capacitor.

### BACKGROUND

In general, various computer memory technologies have been developed in semiconductor industry. A fundamental building block of a computer memory may be referred to as memory cell. The memory cell may be an electronic circuit that is configured to store at least one information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained (read out) by determining in which of the memory states the memory cell is residing in. At present, various types of memory cells may be used to store data. By way of example, a type of memory cell may include a thin film of a spontaneous-polarizable material, e.g., a ferroelectric material or a configuration of an anti-ferroelectric material, whose polarization state may be changed in a controlled fashion to store data in the memory cell, e.g., in a non-volatile manner. A memory cell or an arrangement of memory cells may be integrated, for example, on a wafer or a chip together with one or more logic circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A and FIG. 1B each show various aspects of a capacitive memory structure in a schematic view;

FIG. 2A to FIG. 2I each show an exemplary configuration of a spontaneously polarizable capacitor structure according to various aspects;

FIG. 3A to FIG. 3D each show a second sublayer according to various aspects;

FIG. 4A and FIG. 4B show a polarization/electric field characteristic for a configuration of the spontaneously polarizable capacitor structure according to FIG. 2A and according to FIG. 2E, respectively;

FIG. 5A and FIG. 5B show a respective current/voltage drop characteristic for a configuration of the spontaneously polarizable capacitor structure according to FIG. 2E and FIG. 5C shows a current/voltage drop characteristic for a configuration of the spontaneously polarizable capacitor structure according to FIG. 2A;

FIG. 6 shows a flow diagram of a method for processing a memory capacitor according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

In the semiconductor industry, the integration of non-volatile memory technologies, sensor technologies, transmitter technologies, electronic filter technologies, receiver technologies, and the like may be useful for various types of devices and applications. According to various aspects, an electronic device, e.g., a non-volatile memory may be integrated on a chip.

Various aspects relate to a memory cell and a capacitive memory structure, each having a memory capacitor having a memory element with spontaneously polarizable properties. This kind of structure may be referred to as spontaneously polarizable capacitor structure. The memory capacitor may include or may consist of a spontaneously polarizable material. The memory element may include a spontaneously polarizable memory layer stack (e.g., having the spontaneously polarizable properties). The spontaneously polarizable memory layer stack may include an alternative sequence of first sublayers and second sublayers. According to various aspects, the alternating sequence of first sublayers and second sublayers may start with one of the first sublayers and may end with another one of the first sublayers. This may reduce an initial imprint of the spontaneously polarizable memory layer stack, thereby shifting the current/voltage drop characteristic to lower voltage values. According to various aspects, each of the second sublayers may include (e.g., consists of) a centration of a second transition metal which is substantially different (e.g., substantially more (e.g., substantially greater)) than a concentration of a first transition metal. This may increase the Curie temperature of the spontaneously polarizable memory layer stack, thereby reducing a pinching behavior of the spontaneously polarizable memory layer stack. A combination of the above measures may result in a substantially perfect polarization/electric field hysteresis loop.

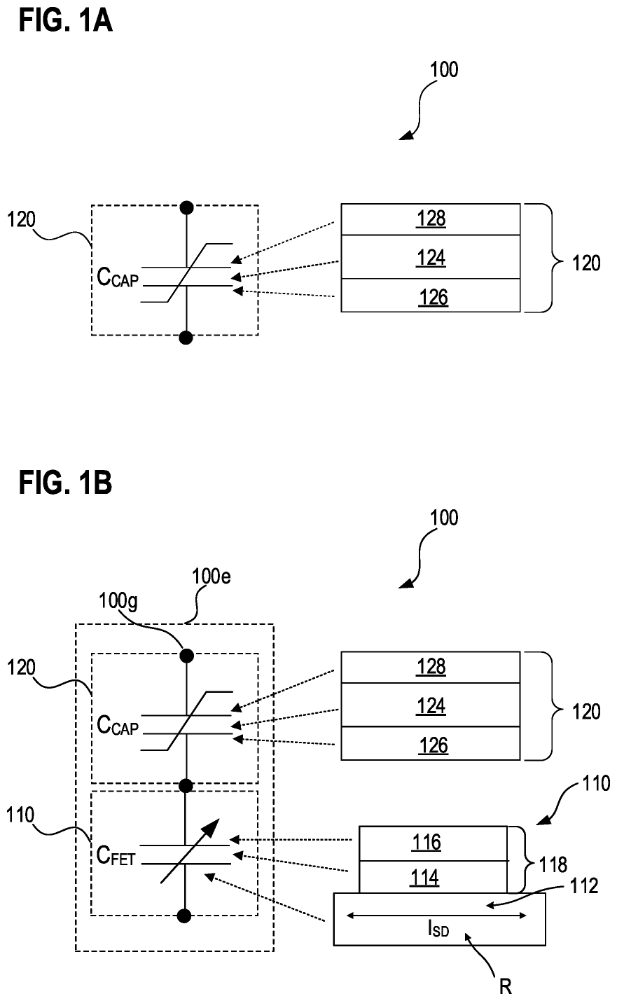

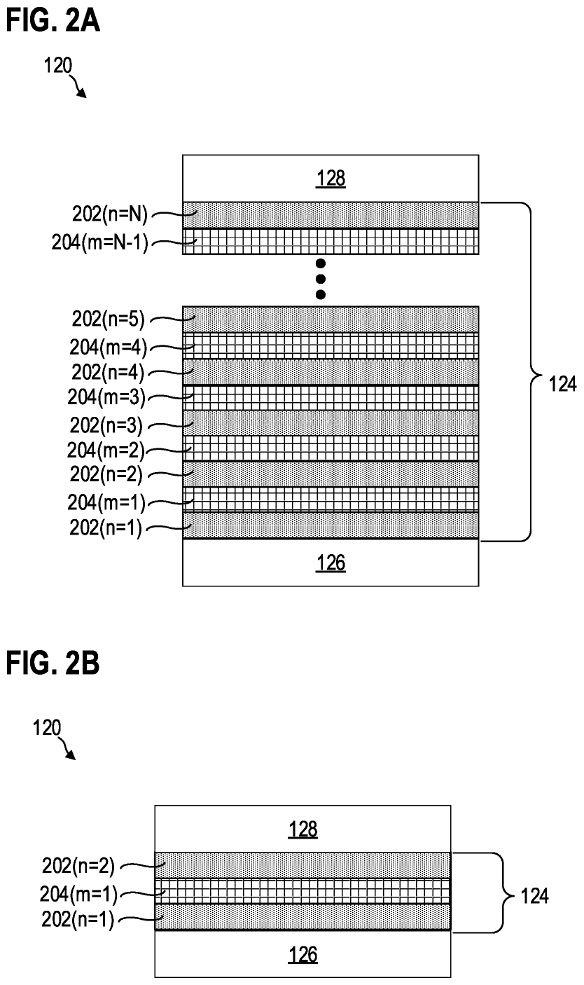

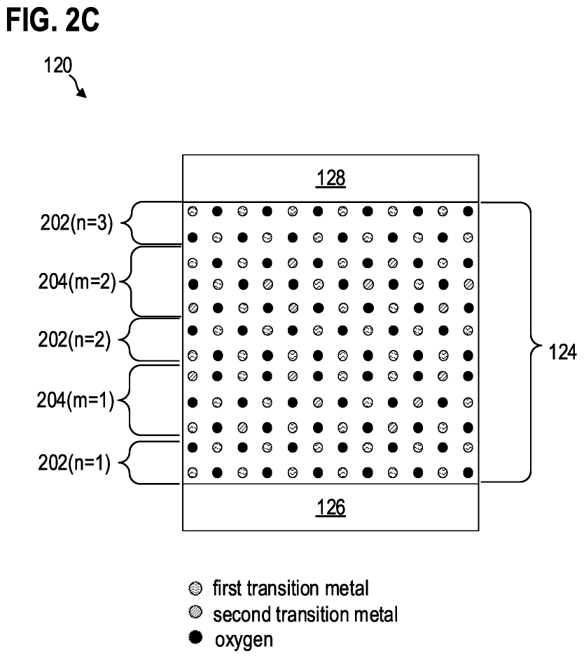

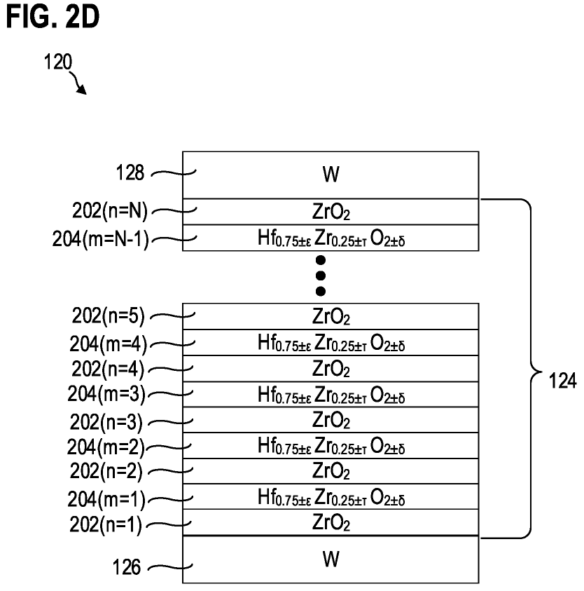

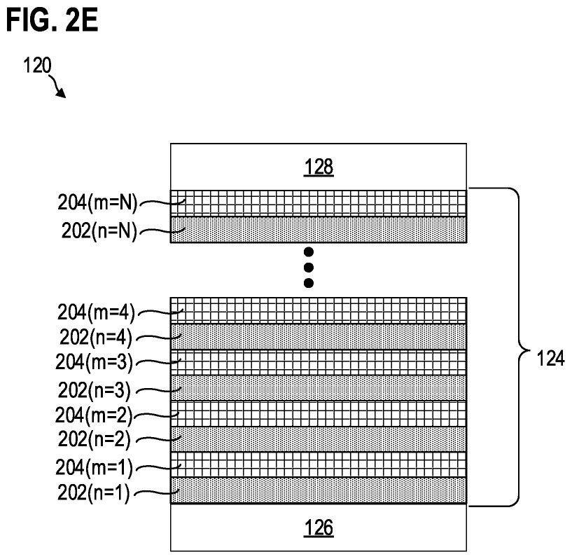

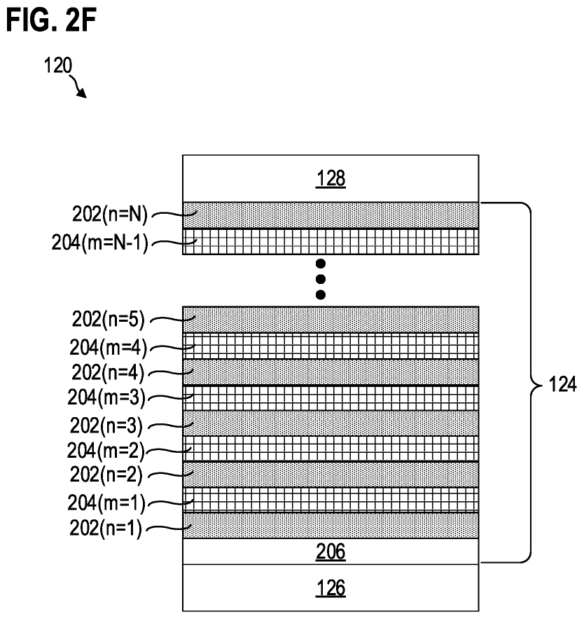

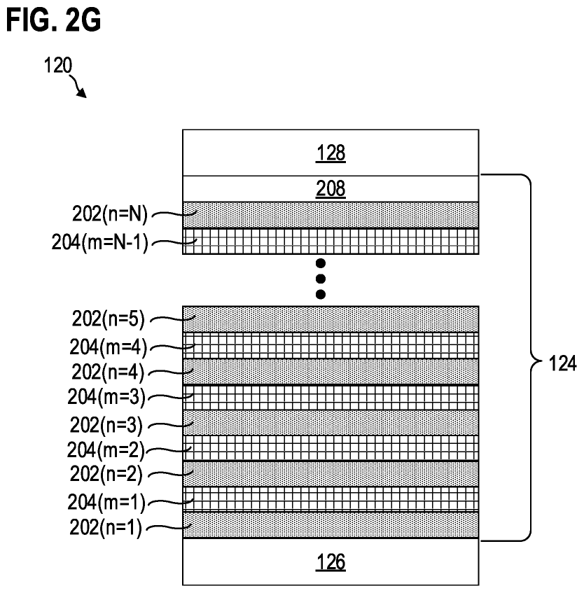

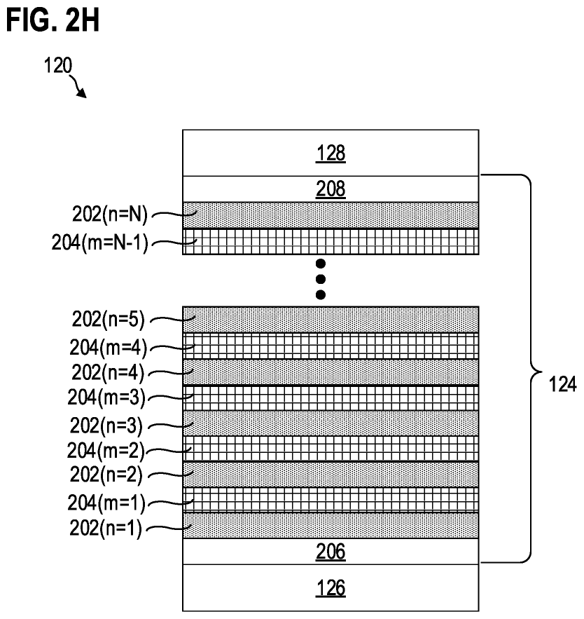

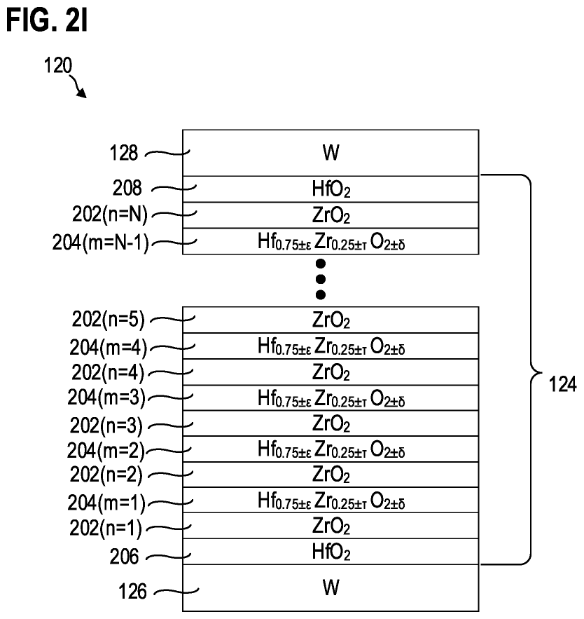

FIG. 1A shows various aspects of a memory structure 100. The memory structure 100 may include a capacitive memory structure, such as a spontaneously polarizable capacitor, SPOC, structure 120. The SPOC structure 120 may include at least two electrodes (e.g., two electrode layers), such as a first electrode 126 and a second electrode 128. The SPOC structure 120 may include a memory element 124. The memory element 124 may be disposed between the first electrode 126 and the second electrode 128. The memory element 124 may be disposed in direct physical contact with the first electrode 126 and in direct physical contact with the second electrode 128. The memory element 124 may include or may consist of a spontaneously polarizable material. A memory element including or consisting of a spontaneously polarizable material may also be referred to as spontaneously-polarizable memory element 124. For example, the spontaneously polarizable material may be a remanent polarizable material, such as a ferroelectric material, or a non-remanent polarizable material, such as an anti-ferroelectric material. A memory element including or consisting of a spontaneously polarizable material may be understood such that the memory element has (e.g., within the framework of the SPOC structure 120) spontaneously polarizable properties. As described with reference to FIG. 2A to FIG. 2I below, the memory element may include a memory layer stack including a plurality of sublayers. The memory element 124 may have the spontaneously polarizable properties even in the case that some of the sublayers are not spontaneously polarizable. According to various aspects, the first electrode 126, the second electrode 128, and the memory element 124 may form the SPOC structure 120. The SPOC structure 120 may, in some aspects, also be referred to as memory capacitor.

The spontaneously-polarizable memory element 124 may show a hysteresis in the (voltage (drop) dependent) polarization. The spontaneously-polarizable memory element 124 may show non-remanent spontaneous polarization (e.g., may show anti-ferroelectric properties), e.g., the spontaneously-polarizable memory element may have no or no substantial remanent polarization remaining in the case that no voltage drops over the spontaneously-polarizable memory element 124. In other aspects, the spontaneously-polarizable memory element 124 may show remanent spontaneous polarization (e.g., may show ferroelectric properties), e.g., the spontaneously-polarizable memory element 124 may have a remanent polarization or a substantial remanent polarization remaining in the case that no voltage drops over the spontaneously-polarizable memory element.

The terms “spontaneously polarized” or “spontaneous polarization” may be used herein, for example, with reference to the polarization capability of a material beyond dielectric polarization. A “spontaneously-polarizable” (or “spontaneous-polarizable”) material may be or may include a spontaneously-polarizable material that shows a remanence, e.g., a ferroelectric material, and/or a spontaneously-polarizable material that shows no remanence, e.g., an anti-ferroelectric material. The coercivity of the spontaneously-polarizable material may be a measure of the strength of the reverse polarizing electric field that may be required to remove a remanent polarization.

A spontaneous polarization (e.g., a remanent or non-remanent spontaneous polarization) may be evaluated via analyzing one or more hysteresis measurements (e.g., hysteresis curves), e.g., in a plot of polarization, P, versus electric field, E, in which the material is polarized into opposite directions. The polarization capability of a material (dielectric polarization, spontaneous polarization, and a remanence characteristics of the polarization) may be analyzed using capacity spectroscopy, e.g., via a static (C-V) and/or time-resolved measurement or by polarization-voltage (P-V) or positive-up-negative-down (PUND) measurements.

According to various aspects, in various types of applications, e.g., in memory technology, a remanent polarization as low as 0 μC/cm² to 3 μC/cm² may be regarded as no substantial remanent polarization. Such low values of a remanent polarization may be present in a layer or material due to undesired effects, e.g., due to a not ideal layer formation. According to various aspects, in various types of applications, e.g., in memory technology, a remanent polarization greater than 3 μC/cm² may be regarded as substantial remanent polarization. Such a substantial remanent polarization may allow for storing information as a function of a polarization state of a spontaneously polarizable layer or a spontaneously polarizable material.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a spontaneous polarization of a material similar to ferromagnetism and anti-ferromagnetism used to describe remanent magnetization in magnetic materials. According to various aspects, an electric coercive field, E_{C}, (also referred to as coercive field) may be or may represent the electric field required to depolarize a remanent-polarizable layer.

According to various aspects, the spontaneously-polarizable memory element 124 may include or may consist of a remanent-polarizable material. A remanent-polarizable material may be a material that is remanently polarizable and shows a remanence of the spontaneous polarization, such as a ferroelectric material. In other aspects, remanent-polarizable material may be a material that is spontaneously polarizable and that shows no remanence, e.g., an anti-ferroelectric material under the additional conditions that measures are implemented to generate an internal electric-field within the anti-ferroelectric material. Hence, a non-remanently polarizable material, such as an anti-ferroelectric (“antiferroelectric”) material may exhibit remanent polarizable properties within certain structures. An internal electric-field within an anti-ferroelectric material may be caused (e.g., applied, generated, maintained, as examples) by various strategies: e.g., by implementing floating nodes that may be charged to voltages different from zero volts, and/or by implementing charge storage layers, and/or by using doped layers, and/or by using electrode layers that adapt electronic work-functions to generate an internal electric field, by using an encapsulation structure which introduces compressive stress or tensile stress onto the memory element 124, thereby establishing the spontaneously polarizable properties, only as examples. The spontaneously-polarizable memory element 124 including or being made of a remanent-polarizable material may be referred to herein as remanent-polarizable memory element (e.g., as remanent-polarizable layer).

In some aspects, the spontaneous-polarizable material (e.g., a remanent-polarizable material) may be based on at least one metal oxide. Illustratively, a composition of the spontaneous-polarizable material may include the at least one metal oxide for more than 50%, or more than 66%, or more than 75%, or more than 90%. In some aspects, the spontaneous-polarizable material may include one or more metal oxides. The spontaneous-polarizable material may include (or may be based on) at least one of HfₐO_{b}, ZrₐO_{b}, SiₐO_{b}, YₐO_{b}, as examples, wherein the subscripts “a” and “b” may indicate the number of the respective atom in the spontaneous-polarizable material.

In some aspects, the spontaneous-polarizable material (e.g., the remanent-polarizable material) may be or may include a ferroelectric material, illustratively the memory element 124 may be ferroelectric memory element (for example a ferroelectric layer). A ferroelectric material may be an example of a material used in a spontaneously-polarizable memory element (e.g., in a remanent-polarizable element). The ferroelectric material may be or may include at least one of the following: hafnium oxide (ferroelectric hafnium oxide, HfO₂), zirconium oxide (ferroelectric zirconium oxide, ZrO₂), a (ferroelectric) mixture of hafnium oxide and zirconium oxide. Ferroelectric hafnium oxide may include any form of hafnium oxide that may exhibit ferroelectric properties. Ferroelectric zirconium oxide may include any form of zirconium oxide that may exhibit ferroelectric properties. This may include, for example, hafnium oxide, zirconium oxide, a solid solution of hafnium oxide and zirconium oxide (e.g., but not limited to it, a 1:1 mixture) or hafnium oxide and/or zirconium oxide doped or substituted with one or more of the following elements (non-exhaustive list): silicon, aluminum, gadolinium, yttrium, lanthanum, strontium, zirconium, any of the rare earth elements or any other dopant (also referred to as doping agent) that is suitable to provide or maintain ferroelectricity in hafnium oxide or zirconium oxide. The ferroelectric material may be doped at a concentration from about 2 mol % to about 6 mol %, only as an example.

In some aspects, the spontaneous-polarizable material may include hafnium oxide (e.g., may consist of hafnium oxide, hafnium zirconium oxide (e.g., Hf_{0.75} Zr_{0.25}O₂ or Hf_{0.5} Zr_{0.5} O₂), hafnium silicon oxide hafnium lanthanum oxide or hafnium lanthanum zirconium oxide), zirconium oxide, and/or aluminum nitride (e.g., may consist of aluminum nitride, aluminum scandium nitride or aluminum boron nitride). In some aspects, the spontaneous-polarizable material may include or may consist of Hf₁₋ₓZrₓO₂, Hf₁₋ₓSiₓO₂, Hf₁₋ₓLaₓO₂, Hf_{1-x-y}LaₓZr_{y}O₂, Al₁₋ₓScₓN, or Al₁₋ₓBₓN.

The spontaneously polarizable material of the memory element 124 may include or may consist of lead zirconate titanate (Pb[ZrₓTi₁₋ₓ]O₃, PZT) or strontium bismuth tantalate (Sr₂Bi₂TaO₉, SBT). However, there are several disadvantages for integrating PCT and SBT in complementary metal-oxide-semiconductor (CMOS):
Polycrystalline PZT or SBT films may require a thickness of more than 70 nm in order to ensure that the complete film is ferroelectric. However, the lateral dimension in CMOS integration may not be scalable such that the thick films lead to huge height difference between the SPOC structure 120 and the logic area forming below the interlayer metallization.
PZT and SBT require four elements and cannot be deposited using atomic layer deposition (ALD). Hence, PZT and SBT cannot be used for a 3D-integration of the SPOC structure 120, but merely for planar structures.
PZT and SBT include elements which may contaminate CMOS facilities. PZT even includes lead (Pb) which is considered toxic. This may require a special encapsulation of the whole SPOC structure 120. Further, dedicated tools may be required for depositing the toxic elements.
PZT and SBT have a comparatively small band gap (e.g., 3.0 to 3.5 eV for PZT). Hence, PZT and SBT cannot be used for devices that require low leakage currents through the SPOC structure 120.

As described, the spontaneously polarizable material of the memory element 124 may consist of hafnium zirconium oxide (Hf₁₋ₓZrₓO₂, HZO) with 0≤x≤1 (i.e., consisting of hafnium oxide in the case of x=0 and consisting of zirconium oxide in the case of x=1). There are several advantages of HZO for CMOS integration:
HZO films are ferroelectric or antiferroelectric down to a thickness of 1 nm. Hence, the integration of the SPOC structure 120 in lateral dimension is scalable to a maximum degree.
HZO films can be deposited using ALD. This allows to manufacture SPOC structure 120 having curved structures and allow a 3D-integration of the SPOC structure 120.
HZO films are CMOS compatible and do not include any toxic elements. Hence, an encapsulation of the SPOC structure 120 may be optional and the standard CMOS equipment can be used.
It may be possible to crystallize the HZO into the ferroelectric phase by annealing at temperatures in a range from about 300° C. to about 400° C. This allows an integration of the SPOC structure 120 as part of the interlayer metallization.
HZO films have a large band gap (e.g., 5.8 eV for hafnium oxide). Thus, HZO can be used for devices that require a low leakage current.

According to various aspects, the memory capacitor as provided by the SPOC structure 120 may be or may include a ferroelectric capacitor (FeCAP) or an anti-ferroelectric capacitor (AFeCAP). An information may be stored by the memory capacitor via at least two remanent polarization states of the SPOC structure 120. The programming of the SPOC structure 120 (illustratively the storage of information therein) may be carried out by providing (e.g., applying) an electric field to thereby set or change the remanent polarization state of the spontaneously polarizable memory element 124. Illustratively, the spontaneous-polarizable material (e.g., a ferroelectric material, e.g., an anti-ferroelectric material) may be used to store data in non-volatile manner in integrated circuits.

It may be understood that, even though various aspects refer to a memory element including or being made of a spontaneously-polarizable material, other memory elements whose state may be altered by an electric field provided across a capacitive memory structure may be used as long as the structure of the material can be changed via application of an electric field, as described herein.

The SPOC structure 120 may have a capacitive configuration with a (first) capacitance, C_{CAP}, associated therewith (see equivalent circuit 100e in FIG. 1A with respect to the capacitive properties). The first electrode 126, the memory element 124, and the second electrode 128 may form a memory capacitor layer stack. In some aspects, the memory capacitor layer stack may be a planar layer stack; however, other shapes may be suitable as well, e.g., curved shapes, angled shapes, coaxially aligned shapes, as examples. Illustratively, the SPOC structure 120 may include planar electrodes, or, in other aspects, the SPOC structure 120 may be configured as 3D capacitor including, for example, angled or curved electrodes.

With reference to FIG. 1B, the memory structure 100 may be a field-effect transistor (FET) based capacitive memory structure. The memory structure 100 may include a field-effect transistor structure 110 and the capacitive memory structure (e.g., the SPOC structure 120). The SPOC structure 120 may be coupled to the field-effect transistor structure 110. The field-effect transistor structure 110 may include a gate structure 118, wherein the gate structure 118 may include a gate isolation 114 and a gate electrode 116. The gate structure 118 is illustrated exemplarily as a planar gate stack; however, it is understood that the planar configurations shown in FIG. 1A and FIG. 1B are examples, and that other field-effect transistor designs may include a gate structure 118 with a non-planar shape, for example a trench gate transistor design, a vertical field-effect transistor design, or other designs, such as a fin-FET design.

The gate structure 118 may define a channel region 112, e.g., provided in a semiconductor portion (e.g., in a semiconductor layer, in a semiconductor die, etc.). The gate structure 118 may allow for a control of an electrical behavior (e.g., a resistance R) of the channel region 112, e.g., a current flow in the channel region 112 may be controlled (e.g., allowed, increased, prevented, decreased, etc.). In some aspects, the gate structure 118 may, for example, allow to control (e.g., allow or prevent) a source/drain current, I_{SD}, from a first source/drain region of the field-effect transistor structure 110 to a second source/drain region of the field-effect transistor structure 110 (the source/drains are provided in or adjacent to the channel but are not shown in FIG. 1B). The channel region 112 and the source/drain regions may be formed, e.g., via doping one or more semiconductor materials or by the use of intrinsically doped semiconductor materials, within a layer and/or over a layer. With respect to the operation of the field-effect transistor structure 110, a voltage may be provided at the gate electrode 116 to control the current flow, I_{SD}, in the channel region 112, the current flow, I_{SD}, in the channel region 112 being caused by voltages supplied via the source/drain regions.

According to various aspects, the semiconductor portion (illustratively, where the channel region 112 may be formed), may be made of or may include silicon. However, other semiconductor materials of various types may be used in a similar way, e.g., germanium, Group III to V (e.g., SiC), or other types, including for example carbon nanotubes, organic materials (e.g., organic polymers), etc. In various aspects, the semiconductor portion may be a wafer made of silicon (e.g., p-type doped or n-type doped). In other aspects, the semiconductor portion may be a silicon on insulator (SOI) wafer. In other aspects, the semiconductor portion may be provided by a semiconductor structure, e.g., by one or more semiconductor fins, one or more semiconductor nanosheets, one or more semiconductor nanowires, etc., disposed at a carrier.

The gate electrode 116 may include an electrically conductive material, for example, a metal, a metal alloy, a degenerate semiconductor (in other words a semiconductor material having such a high level of doping that the material acts like a metal and not anymore as a semiconductor), and/or the like. As an example, the gate electrode 116 may include or may be made of aluminum. As another example, the gate electrode 116 may include or may be made of polysilicon. According to various aspects, the gate electrode 116 may include one or more electrically conductive portions, layers, etc. The gate electrode 116 may include, for example, one or more metal layers (also referred to as a metal gate), one or more polysilicon layers (also referred to as poly-Si-gate), etc. A metal gate may include, for example, at least one work-function adaption metal layer disposed over the gate isolation 114 and an additional metal layer disposed over the work-function adaption metal layer. A poly-Si-gate may be, for example, p-type doped or n-type doped.

The gate isolation 114 may be configured to provide an electrical separation of the gate electrode 116 from the channel region 112 and further to influence the channel region 112 via an electric field generated by the gate electrode 116. The gate isolation 114 may include one or more electrically insulating layers, as an example. Some designs of the gate isolation 114 may include at least two layers including different materials, e.g., a first gate isolation layer (e.g., a first dielectric layer including a first dielectric material) and a second gate isolation layer (e.g., a second dielectric layer including a second dielectric material distinct from first dielectric material).

As illustrated by the circuit equivalent in FIG. 1A, a (second) capacitance, C_{FET}, may be associated with the field-effect transistor structure 110. Illustratively, the channel region 112, the gate isolation 114, and the gate electrode 116 may have a capacitance, C_{FET}, associated therewith, originating from the more or less conductive regions (the channel region 112 and the gate electrode 116) separated from one another by the gate isolation 114. Further illustratively, the channel region 112 may be considered as a first capacitor electrode, the gate electrode 116 as a second capacitor electrode, and the gate isolation 114 as a dielectric medium between the two capacitor electrodes. The capacitance, C_{FET}, of the field-effect transistor structure 110 may define one or more operating properties of the field-effect transistor structure 110. The configuration of the field-effect transistor structure 110 (e.g., of the gate isolation 114) may be adapted according to a desired behavior or application of the field-effect transistor structure 110 during operation (e.g., according to a desired capacitance).

In general, the capacitance, C, of a planar capacitor structure may be expressed as,

C=ε₀εᵣA/d,

with so being the relative permittivity of the vacuum, A being the effective area of the capacitor, d being the distance of the two capacitor electrodes from one another, and εᵣ being the relative permittivity of the dielectric material disposed between two capacitor electrodes assuming that the whole gap between the two capacitor electrodes is filled with the dielectric material. It is noted that the capacitance of a non-planar capacitor structure or of a modified variant of a planar capacitor structure may be calculated based on equations known in the art.

In some aspects, the gate electrode 116 of the field-effect transistor structure 110 and the first electrode 126 of the SPOC structure 120 that is connected to the field-effect transistor structure 110 may be spatially separated from one another and electrically connected via a conductive connection, e.g., one or more metal lines. In other aspects, the gate electrode 116 of the field-effect transistor structure 110 and the first electrode 126 of the SPOC structure 120 may be in direct physical contact with one another or implemented as a single (shared) electrode. For example, an electrode layer may (as single (shared) electrode) provide both, the gate electrode 116 of the field-effect transistor structure 110 and the first electrode 126 of the SPOC structure 120.

The field-effect transistor structure 110 and the SPOC structure 120 form together a field-effect transistor based (e.g., capacitive) memory structure, as exemplarily shown in FIG. 1A. A gate 100 g of the field-effect transistor based (e.g., capacitive) memory structure may be provided by the second electrode 128 or an additional electrode coupled to the second electrode 128. Various configurations of the SPOC structure 120 are described with reference to FIG. 2A to FIG. 2I.

According to various aspects, the memory structure 100 may provide or may be part of a memory cell. A memory cell may be provided, for example, by coupling a gate of a field-effect transistor structure with a (e.g., spontaneously polarizable) capacitive memory structure, or by integrating a memory structure in the gate structure of a field-effect transistor structure (as shown, in FIG. 1B for the field-effect transistor structure 110 and the SPOC structure 120). A memory cell may illustratively include a field-effect transistor structure and a SPOC structure coupled to or integrated in the field-effect transistor structure (optionally with one or more additional elements). In such a configuration the capacitive memory element) may be in a capacitive environment, e.g., disposed between two electrode layers or disposed between a channel of a field-effect transistor and an electrode layer (e.g., a gate electrode of the field-effect transistor). In such a memory cell, the state (e.g., the polarization state) of the memory element influences the threshold voltage of the field-effect transistor structure (e.g., a first state of the memory element may be associated with a first threshold voltage, such as a low threshold voltage, and a second state of the memory element may be associated with a second threshold voltage, such as a high threshold voltage). A memory cell that includes a field-effect transistor structure and a SPOC structure may be referred to as field-effect transistor based memory cell or field-effect transistor based capacitive memory cell. It is noted that even though various aspects of a memory cell are described herein with reference to a field-effect transistor based capacitive memory structure (such as a FeFET), other memory structures may be suitable as well.

The field-effect transistor structure 110 and the SPOC structure 120 may be coupled (e.g., electrically connected) to one another such that a capacitive voltage divider is provided. The capacitive voltage divider formed by the field-effect transistor structure 110 and the SPOC structure 120 may allow adapting the capacitances C_{FET}, C_{CAP} of the respective capacitors to allow an efficient programming of the memory cell. The overall gate voltage required for switching the memory cell from one memory state into another memory state (e.g., from high threshold voltage state to low threshold voltage state, as described below), may become smaller in case the voltage distribution across the field-effect transistor structure 110 and the SPOC structure 120 is adapted such that more of the applied gate voltage drops across the memory layer of the SPOC structure 120 (e.g., across the memory element 124) than across the gate isolation of the field-effect transistor structure 110. The overall write voltage (illustratively, applied via nodes to which the field-effect transistor structure 110 and the SPOC structure 120 are connected) may thus be reduced by adapting the capacitive voltage divider. The voltage distribution may be determined by voltage divider calculations for a series connection of the capacitors.

That is, in the case that the capacitance, C_{FET}, of the field-effect transistor structure 110 is adapted (e.g., by providing a suitable gate isolation) a predefined fraction of the voltage applied to the series connection may drop across the SPOC structure 120. Accordingly, the electric field generated across the gate isolation of the field-effect transistor structure 110 underneath the SPOC structure 120 could be reduced if desired. This may lead to a reduced interfacial field stress, which may lead to a reduced wear out of the interface due to, for example, charge injection. Therefore, the reduced electric field generated across the gate isolation may lead to improved endurance characteristics of the memory cell, that is, to an increased amount of possible state reversals until the memory cell may lose or change its memory properties.

By increasing the capacitance C_{FET} of the field-effect transistor structure 110 (e.g., by providing a gate isolation including a relatively thick layer of material with high dielectric constant), the depolarization field, E_{Dep}, of the spontaneously polarizable material of the memory element 124 may be reduced. The depolarization field may be expressed by the following set of equations, wherein the indices “FET” refer to the capacitor provided by the field-effect transistor structure 110 and the indices “CAP” refer to the capacitor provided by the SPOC structure 120, as described herein:

$${V}_{F E T} + {V}_{C A P} = 0 ,$$

$$D = {ε}_{0} {ε}_{F E T} {E}_{F E T} = {ε}_{0} {ε}_{C A P} {E}_{C A P} + P ,$$

$${E}_{C A P} ≡ {E}_{D e p} = - {P ( {ε}_{0} {ε}_{C A P} ( \frac{{C}_{F E T}}{{C}_{C A P}} + 1 ) )}^{- 1} .$$

The depolarization field E_{Dep} may be detrimental to data retention since, depending on its magnitude, it may depolarize the remanent-polarizable layer. However, the magnitude may be reduced by increasing the capacitance ratio C_{FET}/C_{CAP}. Accordingly, in case the capacitance C_{FET} of the field-effect transistor structure 110 is increased, the depolarization field is reduced. This in turn improves the data retention of the memory cell.

According to various aspects, a threshold voltage of a field-effect transistor structure (and in a corresponding manner the threshold voltage of a field-effect transistor based memory cell) may be defined as a constant current threshold voltage (referred to as V_{th(ci)}). In this case, the constant current threshold voltage, V_{th(ci)}, may be a determined gate source voltage, V_{GS}, at which the drain current (referred to as I_{D}) is equal to a predefined (constant) current. The predefined (constant) current may be a reference current (referred to as I_{DO}) times the ratio of gate width (W) to gate length (L). The magnitude of the reference current, I_{DO}, may be selected to be appropriate for a given technology, e.g., 0.1 μA. In some aspects, the constant current threshold voltage, V_{th(ci)}, may be determined based on the following equation:

V_{th(ci)}=V_{GS}(at I_{D}=I_{D0}·W/L).

A threshold voltage of a field-effect transistor structure (e.g., of the field-effect transistor structure 110) may be defined by the properties of the field-effect transistor structure (e.g., the materials, the doping, etc.), and it may thus be a (e.g., intrinsic) property of the field-effect transistor structure.

According to various aspects, a memory cell may have at least two distinct memory states associated therewith, for example with two distinct electrical conductivities or two distinct amounts of stored charge that may be determined to determine in which of the at least two distinct states the memory cell is residing in. A memory cell including a field-effect transistor structure may include a first memory state, for example associated with a low threshold voltage state (referred to as LVT associated with the LVT memory state), and a second memory state, for example associated with a high threshold voltage state (referred to as HVT state associated with the HVT memory state). The high threshold voltage state may be, in some aspects, associated with a lower current flow during readout than the low threshold voltage state. The low threshold voltage state may be an electrically conducting state (e.g., associated with a logic memory state “1”, also referred to as a memory state or programmed state) and the high threshold voltage state may be an electrically non conducting state or at least less conducting than the low threshold voltage state (e.g., associated with a logic memory state “0”, also referred to as a memory state or erased state). However, the definition of the LVT state and the HVT state and/or the definition of a logic “0” and a logic “1” and/or the definition of “programmed state” and “erased state” may be selected arbitrarily. Illustratively, the first memory state may be associated with a first threshold voltage of the FET based memory cell, and the second memory state may be associated with a second threshold voltage of the FET based memory cell.

According to various aspects, the residual polarization of the memory element 124 (e.g., the polarization of the spontaneously-polarizable material of the memory element 124) may define the memory state a memory cell is residing in. According to various aspects, a memory cell may reside in a first memory state in the case that the memory element is in a first polarization state, and the memory cell may reside in a second memory state in the case that the memory element is in a second polarization state (e.g., opposite to the first polarization state). As an example, the polarization state of the memory element may determine the amount of charge stored in the SPOC structure 120. The amount of charge stored in the SPOC structure 120 may be used to define a memory state of the memory cell. The threshold voltage of a field-effect transistor structure may be a function of the polarization state of the memory element 124, e.g., may be a function of the amount and/or polarity of charge stored in the SPOC structure 120. A first threshold voltage, e.g., a low threshold voltage V_{L}m, may be associated with the first polarization state (e.g., with the first amount and/or polarity of stored charge), and a second threshold voltage, e.g., a high threshold voltage V_{H-th}, may be associated with the second polarization state (e.g., with the second amount and/or polarity of stored charge). A current flow from nodes to which the field-effect transistor structure and the SPOC structure 120 are coupled may be used to determine the memory state in which the memory cell is residing in.

According to various aspects, writing a memory cell or performing a write operation of a memory cell may include an operation or a process that modifies the memory state the memory cell is residing in from a (e.g., first) memory state to another (e.g., second) memory state. According to various aspects, writing a memory cell may include programming a memory cell (e.g., performing a programming operation of a memory cell), wherein the memory state the memory cell is residing in after programming may be called “programmed state”. For example, programming an n-type FET based memory cell may modify the state the memory cell is residing in from the HVT state to the LVT state, whereas programming a p-type FET based memory cell may modify the state the memory cell is residing in from the LVT state to the HVT state. According to various aspects, writing a memory cell may include erasing a memory cell (e.g., performing an erasing operation of a memory cell), wherein the memory state the memory cell is residing in after the erasing may be called “erased state”. For example, erasing an n-type FET based memory cell may modify the state the memory cell is residing in from the LVT state to the HVT state, whereas erasing a p-type FET based memory cell may modify the state the memory cell is residing in from the HVT state to the LVT state.

According to various aspects, a memory device may include a memory cell and a controller (e.g., a memory controller) configured to operate (e.g., read and write) the memory cell. According to various aspects, a memory cell arrangement may include a memory cell and a controller (e.g., a memory controller) configured to operate (e.g., read and write) the memory cell. It is noted that some aspects are described herein with reference to a memory cell of a memory device and/or with reference to a memory cell of memory cell arrangement; it is understood that a memory device and/or a memory cell arrangement may include a plurality of such described memory cells according to various aspects that can be operated in the same way by the controller, e.g., at the same time or in a time sequence. A memory cell arrangement may further include respective sets of control lines and voltage supply levels configured to operate the one or more memory cells of the memory device and/or the memory cell arrangement.

It is noted that a memory cell arrangement is usually configured in a matrix-type arrangement, wherein columns and rows define the addressing of the memory cells according to the control lines connecting respectively subsets of memory cells of the memory cell arrangement along the rows and columns of the matrix-type arrangement. However, other arrangements may be suitable as well.

The memory cell described herein (e.g., as part of a memory cell arrangement) may be used in connection with any type of suitable controller, e.g., a controller that may generate only two or only three different voltage levels for writing the memory cell (e.g., for writing one or more memory cells of a memory cell arrangement). However, in other aspects, more than four different voltage levels may be used for operating (e.g., for reading) the memory cell or for operating one or more memory cells of a memory cell arrangement.

According to various aspects, the memory cell described herein may be configured complementary metal oxide semiconductor (CMOS) compatible, e.g., including standard CMOS-materials only and may require no special integration considerations (e.g., no special thermal budget which may avoid diffusion and/or contamination during manufacturing). CMOS compatible spontaneously polarizable materials may be used to implement the one or more memory cell based on, for example, HfO₂ and/or ZrO₂. Doped HfO₂ (e.g., Si:HfO₂ or Al:HfO₂) or other suitable spontaneously-polarizable materials may allow for an integration of the spontaneously polarizable layer via known integration schemes.

According to various aspects, a controller may be configured to provide one or more sets of voltage levels to operate a memory cell arrangement (e.g., including a plurality of memory cells). According to various aspects, a writing operation may be provided based on only two voltage levels (e.g., a first supply voltage level VPP and a second supply voltage level VNN). In the case that the CMOS technology provides electrical access to the bulk, all bulks may be connected to VNN or a voltage significantly similar to VNN but such that no diode from bulk to any source/drain region is forward biased.

Various aspects relate to a SPOC 120 which includes (e.g., is formed by) a plurality of sublayers. The plurality of sublayers may include an alternating sequence of first sublayers and second sublayers.

FIG. 2A to FIG. 2I each show an exemplary configuration of the SPOC structure 120 according to various aspects. For illustration, the configurations of the SPOC structure 120 are exemplarily shown for a planar configuration with planar layers. It is noted that other shapes may be suitable as well, such as curved shapes, angled shapes, coaxially aligned shapes, as examples. In this case, any layer described herein may have a non-planar (e.g., curved) structure.

The memory element 124 may include a spontaneously polarizable memory layer stack. The spontaneously polarizable memory layer stack may have spontaneously polarizable properties. The spontaneously polarizable memory layer stack may include a plurality of sublayers. The plurality of sublayers may include a first set of first sublayers 202(n=1 to N) (with “n” being an integer variable and with “N” being any integer number equal to or greater than two) and a second set of second sublayers 204(m=1 to M) (with “m” being an integer variable and with M=N−1 (see, for example, FIG. 2A to FIG. 2D, and FIG. 2F to FIG. 2I) or with M=N (see, for example, FIG. 2E)).

Every second sublayer of the plurality of sublayers (forming the spontaneously polarizable memory layer stack) may be associated with a second sublayer 204(n) of the second set of second sublayers 204(m=1 to M) and every other second sublayer of the plurality of sublayers may be associated with a first sublayer 202(n) of the first set of first sublayers 202(n=1 to N). Hence, the spontaneously polarizable memory layer stack may include an alternating sequence of first sublayers 202(n) and second sublayers 204(m).

With reference to FIG. 2A, the alternating sequence of first sublayers 202(n) and second sublayers 204(m) may start with a first sublayer 202(1) of the first set of first sublayers 202(n=1 to N) and may end with another first sublayer 202(n=N) of the first set of first sublayers 202(n=1 to N). Hence, the first set of first sublayers 202(n=1 to N) may include at least two first sublayers (e.g., the first sublayer 202(1) and the other first sublayer 202(n=N)) and the second set of second sublayers 204(m=1 to M) may include at least one second sublayer (e.g., the first sublayer 204(1)). A corresponding configuration with exactly two first sublayers in the first set of first sublayers 202(n=1 to N with N=2) and exactly one second sublayer in the second set of second sublayers 204(m=1 to M with M=1) is shown in FIG. 2B. Thus, the plurality of sublayers forming the spontaneously polarizable memory layer stack may include an odd number of sublayers (e.g., an even number of first sublayers and an odd number of second sublayers, or an odd number of first sublayers and an even number of second sublayers).

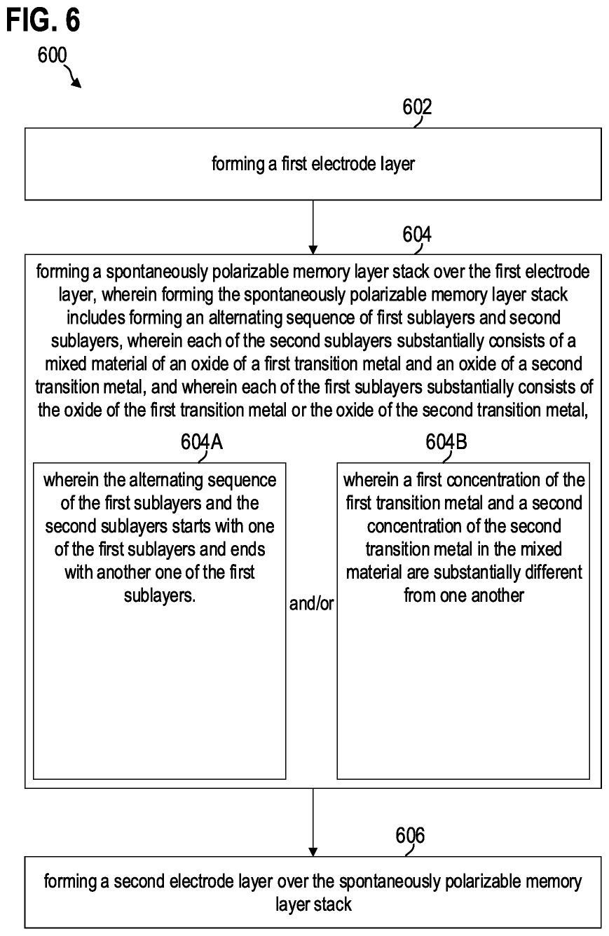

As used herein, a start and an end of the alternating sequence of first sublayers 202(n) and second sublayers 204(m) may refer to a manufacturing of the spontaneously polarizable memory layer stack (see, for example, FIG. 6 and corresponding description). Thus, the start of the alternating sequence of first sublayers 202(n) and second sublayers 204(m) may refer to the sublayer of the plurality of sublayers closest to the first electrode 126 and the end of the alternating sequence of first sublayers 202(n) and second sublayers 204(m) may refer to the sublayer of the plurality of sublayers closest to the second electrode 128. However, it is noted that the order of the alternating sequence of first sublayers 202(n) and second sublayers 204(m) may be set the other way around starting closest to the second electrode 128 and ending closest to the first electrode 126.

The spontaneously polarizable memory layer stack may be disposed in direct physical contact with the first electrode 126 (see, for example, FIG. 2A to FIG. 2E, and FIG. 2G) and/or in direct physical contact with the second electrode 128 (see, for example, FIG. 2A to FIG. 2F). Thus, in the case that the spontaneously polarizable memory layer stack is disposed in direct physical contact with the first electrode 126 and the second electrode 128, the first sublayer 202(1) of the first set of first sublayers 202(n=1 to N) with which the alternating sequence of first sublayers 202(n) and second sublayers 204(m) starts may be disposed in direct physical contact with the first electrode 126 and the first sublayer 202(n=N) of the first set of first sublayers 202(n=1 to N) with which the alternating sequence of first sublayers 202(n) and second sublayers 204(m) ends may be disposed in direct physical contact with the second electrode 128.

Each first sublayer 202(n) of the first set of first sublayers 202(n=1 to N) may have substantially the same thickness or at least one of the first sublayers of the first set of first sublayers 202(n=1 to N) may have a thickness different from the thickness of the other first sublayers in the first set of first sublayers 202(n=1 to N). Each second sublayer 204(m) of the second set of second sublayers 204(m=1 to M) may have substantially the same thickness or at least one of the second sublayers of the second set of second sublayers 204(m=1 to M) may have a thickness different from the thickness of the other second sublayers in the second set of second sublayers 204(m=1 to M). According to some aspects, at least the first sublayer 202(1) of the first set of first sublayers 202(n=1 to N) with which the alternating sequence of first sublayers 202(n) and second sublayers 204(m) starts and the first sublayer 202(n=N) of the first set of first sublayers 202(n=1 to N) with which the alternating sequence of first sublayers 202(n) and second sublayers 204(m) ends may have substantially the same thickness. For example, each first sublayer 202(n=N) of the first set 202(n=1 to N) may have a respective thickness equal to or less than 6 Å. For example, each second sublayer 204(m) of the second set 204(m=1 to M) may have a respective thickness equal to or less than 9 Å (e.g., equal to or less than 8 Å). According to various aspects, a respective thickness of each of the first sublayers 202(n) may be less than a respective thickness of each of the second sublayers, or vice versa.

In the case that the alternating sequence starts with one of the first sublayers (e.g., in direct (physical) contact with the first electrode 126) and ends with another one of the first sublayers (e.g., in direct (physical) contact with the second electrode 128), the interface between the one first sublayer 202(n=1) of the first set 202(n=1 to N) and a neighboring layer closest to the one first sublayer 202(n=1) (e.g., the first electrode 126 or a first interface sublayer) may be symmetric (e.g., at least in terms of a material of the first sublayers) to the interface between the other first sublayer 202(n=N) of the first set 202(n=1 to N) and a neighboring layer closest to the other first sublayer 202(n=N) (e.g., the second electrode 128 or a second interface sublayer). This symmetry of the interfaces may be increased in the case that the neighboring layers (e.g., the first electrode 126 and the second electrode 128, or the first interface sublayer and the second interface sublayer) consist of the same one or more materials (e.g., consist of tungsten in the case of that the electrode 126 and the second electrode 128 are the neighboring layers, or substantially consist of the (first) oxide of the first transition metal or the (second) oxide of the second transition metal in the case that the neighboring layers are the first interface sublayer and the second interface sublayer).

According to various aspects, since the alternating sequence may start with one of the first sublayers and may end with another one of the first sublayers, the spontaneously polarizable memory layer stack may be symmetric having a horizontal symmetry axis. For example, the in the case that “N” is an even integer number, the horizontal center of the second sublayer

$$204 ( m = \frac{N}{2} )$$

may provide the horizontal symmetry axis of the spontaneously polarizable memory layer stack. For example, the in the case that “N” is an odd integer number, the horizontal center of the first sublayer

$$202 ( n = \frac{N + 1}{2} )$$

may provide the horizontal symmetry axis of the spontaneously polarizable memory layer stack. According to various aspects, each first sublayer 202(n) of the first set of first sublayers 202(n=1 to N) may include or may consist of the same material (e.g., also the same stoichiometry) and/or each second sublayer 204(m) of the second set of second sublayers 204(m=1 to M) may include or may consist of the same material (e.g., also the same stoichiometry). Thus, the spontaneously polarizable memory layer stack may also be symmetric with respect to the material. According to various aspects, every second of the first set of first sublayers 202(n=1 to N) may include or may consist of the same first material (e.g., also the same stoichiometry) and every other second of the first set of first sublayers 202(n=1 to N) may include or may consist of the same second material (e.g., also the same stoichiometry) different from the first material, thereby also providing symmetric regarding the horizontal symmetry axis. According to various aspects, the first electrode 126 and the second electrode 128 may have the same thickness and/or may include (e.g., may consist of) the same material such that the SPOC structure 120 may be symmetric regarding the horizontal symmetry axis.

According to various aspects, the SPOC structure 120 may include one or more functional layers between at least one of the first electrode 126 and/or second electrode 128 and the spontaneously polarizable memory layer stack. For example, to ensure the symmetry of the SPOC structure 120, the SPOC structure 120 may include one or more first functional layers between the first electrode 126 and the spontaneously polarizable memory layer stack and one or more second functional layers between the second electrode 128 and the spontaneously polarizable memory layer stack. Here, a thickness and/or a material of the one or more first functional layers may correspond to the one(s) of the one or more second functional layers. According to various aspects, the memory element 124 may include a first interface sublayer between the first electrode 126 and the spontaneously polarizable memory layer stack and/or a second interface sublayer between the second electrode 128 and the spontaneously polarizable memory layer stack (see, for example, FIG. 2F to FIG. 2I).

According to various aspects, each second sublayer 204(m) of the second set of second sublayers 204(m=1 to M) may include (e.g., may substantially consist of) an oxide (e.g., a first oxide) of a first transition metal (in some aspects referred to as first transition-metal-oxide) and an oxide (e.g., a second oxide) of a second transition metal (in some aspects referred to as second transition-metal-oxide). The phrase that a respective second sublayer 204(m) includes (e.g., substantially consists of) the (first) oxide of the first transition metal and the (second) oxide of the second transition metal may be understood to mean that the respective second sublayer 204(m) includes (e.g., substantially consists of) a mixed material of the (first) oxide of the first transition metal and the (second) oxide of the second transition metal. An example of the mixed material of the (first) oxide of the first transition metal and the (second) oxide of the second transition metal may be Hf₁₋ₓZrₓO₂, HZO) with 0<x<1. A mixed material of the (first) oxide of the first transition metal and the (second) oxide of the second transition metal may be understood to mean a material mixture substantially consisting the (first) oxide of the first transition metal and the (second) oxide of the second transition metal. Each first sublayer 202(n) of the first set of first sublayers 202(n=1 to N) may substantially consist of the (first) oxide of the first transition metal or of the (second) oxide of the second transition metal. An exemplary illustration is shown in FIG. 2C for N=3.

According to various aspects, all first sublayers of the first set of first sublayers 202(n=1 to N) may substantially consist of the (first) oxide of the first transition metal or all first sublayers of the first set of first sublayers 202(n=1 to N) may substantially consist of the (second) oxide of the second transition metal. As an illustrative example, the first transition metal may be zirconium and the second transition metal may be hafnium, such that each second sublayer 204(m) of the second set 204(m=1 to M) may include (e.g., may consist of) hafnium zirconium oxide (Hf₁₋ₓZrₓO₂, HZO) with 0<x<1 and that all first sublayers of the first set 202(n=1 to N) may substantially consist of hafnium oxide (HfO₂) or of zirconium oxide (ZrO₂).

According to various aspects, one or more first sublayers of the first set of first sublayers 202(n=1 to N) may substantially consist of the (first) oxide of the first transition metal the other first sublayers of the first set of first sublayers 202(n=1 to N) may substantially consist of the (second) oxide of the second transition metal. As an illustrative example, the first transition metal may be zirconium and the second transition metal may be hafnium, such that the one or more first sublayers may substantially consist of hafnium oxide (HfO₂) and that the other first sublayers may substantially consist of zirconium oxide (ZrO₂).

As an example, the first sublayer 202(1) closest to the first electrode 126 and the first sublayer 202(n=N) closest to the second electrode may substantially consist of the (first) oxide of the first transition metal and all other first sublayers 202(n=2 to N−1) may substantially consist of the (second) oxide of the second transition metal, or vice versa.

The phrase that a layer “substantially consists of” a material, as used herein, may be understood to mean that the layer may include other materials; however, a concentration of the other materials may be significantly lower than a concentration of the material. That the layer “substantially consists of” the material may be understood to mean that the layer includes at least 80 at. % (e.g., at least 90 at. %, e.g., at least 95 at. %, e.g., about 100 at. %) of the material (e.g., of the (first) oxide of the first transition metal or the (second) oxide of the second transition metal in the case of each first sublayer, as described herein) or more (hence, the concentration of the material may be equal to or greater than 80 at. %). For example, that a respective first sublayer 202(n) of the first set 202(n=1 to N) may substantially consist of zirconium oxide (ZrO₂) may be understood to mean that a concentration of zirconium oxide within the respective first sublayer 202(n) may be equal to or greater than 80 at. %. As an example, a first sublayer 202(n) may consist of hafnium zirconium oxide, Hf₁₋ₓZrₓO₂, with 0.8<x<1. For example, in the case that each second sublayer 204(m) of the second set 204(m=1 to M) may include (e.g., may consist of) hafnium zirconium oxide and each first sublayer 202(n) of the first set 202(n=1 to N) may substantially consist of zirconium oxide (ZrO₂), some hafnium atoms may diffuse from a second sublayer into a first sublayer such that the first sublayer may include a small amount of hafnium atoms such that a second sublayer which substantially consists of zirconium oxide may consists of hafnium zirconium oxide, Hf₁₋ₓZrₓO₂, with 0.95≤x≤1, as an example. It is understood that a first sublayer 202(n) may completely consist of the first transition-metal-oxide (e.g., zirconium oxide or hafnium oxide).

As used herein, a “concentration” of an element (e.g., of a transition metal) may refer to an atomic percentage (in at. %) of the element. Thus, in the case that the concentration of one element is compared to the concentration of another element, the atomic percentage of the one element may be compared to the atomic percentage of the other element. It is understood that a relation between the atomic percentage of the one element and the atomic percentage of the other element may directly refer to an atomic ratio between the one element and the other element. For example, in the case that the concentration (e.g., the atomic percentage) of the one element may be two times the concentration (e.g., the atomic percentage) of the other element, the atomic ratio between the one element and the other element may be 2 to 1 (2:1).

According to various aspects, each second sublayer 204(m) of the second set 204(m=1 to M) may include a first concentration of the first transition metal and a second concentration of the second transition metal. The second concentration of the second transition metal may be substantially different from the first concentration of the first transition metal within at least one (e.g., each) second sublayer 204(m) of the second set 204(m=1 to M). The phrase “substantially different”, as used herein, may be understood to mean that either the first concentration is substantially more than the second concentration or that the second concentration is substantially more than the first concentration. In the following, for illustrative purposes, the second concentration is described to be substantially more than the first concentration. However, it is understood that the first concentration may be substantially more than the second concentration in an analogous manner. Thus, various aspects are described in which the second concentration of the second transition metal may be substantially more than the first concentration of the first transition metal within at least one (e.g., each) second sublayer 204(m) of the second set 204(m=1 to M). The phrase that the second concentration may be “substantially more” than the first concentration, as used herein, may be understood to mean that the second concentration of the second transition metal is at least 1.5-times the first concentration of the first transition metal. For example, the second concentration of the second transition metal may be at least twice the first concentration of the first transition metal. In the exemplary case that a second sublayer 204(m) includes hafnium zirconium oxide, Hf₁₋ₓZrₓO₂, the second concentration of the second transition metal, Hf, may be substantially more than the first concentration of the first transition metal, Zr, such that 0<x≤0.4. Hence, a concentration of the (second) oxide of the second transition metal (e.g., of HfO₂) may be equal to or greater than 60 at. % (e.g., equal to or greater than 55 at. %, e.g., equal to or greater than 70 at. %, e.g., equal to or greater than 75 at. %, etc.). According to various aspects, in the case that the second concentration is only for some of the second sublayers substantially more than the first concentration, the second sublayers of the second set 204(m=1 to M) may be configured such that the second sublayers of the second set 204(m=1 to M) include, on average, a concentration of the (second) oxide of the second transition metal of equal to or greater than 60 at. % (e.g., equal to or greater than 75 at. %, e.g., equal to or greater than 75 at. %). According to various aspects, the spontaneously polarizable memory stack may be configured such (e.g., based on a thickness ratio between the first sublayers and the second sublayers and/or based on a ratio between the second concentration and the first concentration) that even in the case that all second sublayers of the second set 204(m=1 to M) consist of the (first) oxide of the first transition metal, an overall concentration of the oxide of the first transition metal (within the spontaneously polarizable memory stack) may be equal to or less than 65 at. % (e.g., equal to or less than 60 at. %). This may not be achieved in the case that the second concentration and the first concentration would be the same.

An exemplary SPOC structure 120 is shown in FIG. 2D. Here, the first transition metal may be zirconium and the second transition metal may be hafnium such that each first sublayer 202(n) of the first set 202(n=1 to N) may substantially consist of zirconium oxide (ZrO₂) and that each second sublayer 204(m) of the second set 204(m=1 to M) may substantially consist of hafnium zirconium oxide. In this example, the second concentration of hafnium may be three times the first concentration of zirconium such that each second sublayer 204(m) of the second set 204(m=1 to M) may substantially consist of Hf_{0.75±ε}Zr_{0.25±τ}O_{2±δ}. Here, concentration variations “ε”, “τ”, and “δ” may define a fluctuation of around Hf_{0.75}Zr_{0.25}O₂. The hafnium concentration variation ε within the second sublayers may be in a range from about 0 to about 0.05. The zirconium concentration variation T within the second sublayers 204(m) may be in a range from about 0 to about 0.05. The oxygen concentration variation δ within the second sublayers 204(m) may be in a range from about 0 to about 0.5. It is understood that each second sublayer may have a composition within the concentration variations. However, the respective composition of the second sublayers may vary within the concentration variations (e.g., one of the second sublayers may have a hafnium concentration within 0.75±ε but different from the hafnium concentration of another one of the second sublayers (but still within 0.75±ε). It is understood that there may be also an oxygen concentration variation, σ (e.g., in range from about 0 to about 0.5) within the zirconium oxide (ZrO_{2±σ}). According to another example, each second sublayer 204(m) of the second set 204(m=1 to M) may substantially consist of Hf_{0.7±ε}Zr_{0.3±τ}O_{2±6}.

In this example, both, the first electrode 126 and the second electrode 128, may include (e.g., may consist of) tungsten. According to various aspects, respective thickness of each first sublayer 202(n) and the respective thickness of each second sublayer 204(m) may, in combination with the stoichiometry of the first sublayers and the stoichiometry of the second sublayers, selected such that an overall concentration of the (first) oxide of the first transition metal (within the spontaneously polarizable memory stack) may be equal to or less than 65 at. % (e.g., equal to or less than 60 at. %). For example, in the case of the configuration according to FIG. 2D, the respective thickness of each first sublayer 202(n) may be about 6 Å and the respective thickness of each second sublayer 204(m) may be about 8 Å. This may result in an overall concentration (may, in some aspects, also be referred to as overall content) of the (first) oxide of the first transition metal, i.e., ZrO₂ in FIG. 2D, of about 60 at. % (as compared to 40 at. % of HfO₂). It is found that, in the case that the first transition metal is zirconium and the second transition metal is hafnium, reducing the overall content of zirconium oxide within the spontaneously polarizable memory layer stack to below to 65 at. % (e.g., to about 60 at. %) reduces the annealing temperature (required to crystallize the spontaneously polarizable material of the spontaneously polarizable memory layer stack) to 600° C. (or even less than 600° C.) while still no pinching occurs at the operation temperature of about 85° C.

According to various aspects, the spontaneously polarizable memory stack may not end with a first sublayer 202(n=N) but with a second sublayer 204(m=N) as shown in FIG. 2E. As described herein, the start and end of the spontaneously polarizable memory stack may be changed such that the spontaneously polarizable memory stack may start with a first sublayer 202(n=1) (e.g., in direct physical contact with the second electrode 128) and may end with the second sublayer 204(m=N) (e.g., in direct physical contact with the first electrode 126).

With reference to FIG. 2F, the memory element 124 may include a first interface sublayer 206. The first interface sublayer 206 may be disposed in direct physical contact with the first electrode 126. Hence, the first interface sublayer 206 may provide an interface of the memory element 124 to the first electrode 126. With reference to FIG. 2G, the memory element 124 may include a second interface sublayer 208. The second interface sublayer 208 may be disposed in direct physical contact with the second electrode 128. Hence, the second interface sublayer 208 may provide an interface of the memory element 124 to the second electrode 128. As shown in FIG. 2H, the SPOC structure 120 may include both, the first interface sublayer 206 and the second interface sublayer 208. The first interface sublayer 206 and the second interface sublayer 208 may substantially consist of the same material and/or may have substantially the same thickness. This may ensure the horizontal symmetry described herein.

The first interface sublayer 206 and/or the second interface sublayer 208 may be disposed in direct physical contact with the spontaneously polarizable memory layer stack of the memory element 124. Alternatively, one or more first additional layers may be disposed between the first interface sublayer 206 and the spontaneously polarizable memory layer stack and/or one or more second additional layers may be disposed between the second interface sublayer 208 and the spontaneously polarizable memory layer stack.

According to various aspects, the first interface sublayer 206 and/or the second interface sublayer 208 may substantially consist of the (first) oxide of the first transition metal or of the (second) oxide of the second transition metal. As an example, the first interface sublayer 206 and/or the second interface sublayer 208 may substantially consist of the (first or second) oxide the first sublayers of the first set of first sublayers 202(n=1 to N) substantially consist of. As another example, the first interface sublayer 206 and/or the second interface sublayer 208 may substantially consist of the other (first or second) oxide as compared to the oxide all first sublayers of the first set of first sublayers 202(n=1 to N) substantially consist of. Hence, according to this other example, in the case that all first sublayers substantially consist of the (first) oxide of the first transition metal, the first interface sublayer 206 and/or the second interface sublayer 208 may substantially consist of the (second) oxide of the second transition metal, and vice versa. According to a further example, the first interface sublayer 206 may substantially consist of the (first) oxide of the first transition metal in the case that the first sublayer 202(1) which is closest to the first interface sublayer 206 substantially consists of the (second) oxide of the second transition metal and may substantially consist of the (second) oxide of the second transition metal in the case that the first sublayer 202(1) which is closest to the first interface sublayer 206 substantially consists of the (first) oxide of the first transition metal. Accordingly, the second interface sublayer 208 may substantially consist of the (first) oxide of the first transition metal in the case that the first sublayer 202(n=N) which is closest to the second interface sublayer 208 substantially consists of the (second) oxide of the second transition metal and may substantially consist of the (second) oxide of the second transition metal in the case that the first sublayer 202(n=N) which is closest to the second interface sublayer 208 substantially consists of the (first) oxide of the first transition metal. According to an even further example, the first interface sublayer 206 and/or the second interface sublayer 208 may include (e.g., may substantially consist of) the (first) oxide of the first transition metal and the (second) oxide of the second transition metal. In this case, the first interface sublayer 206 and/or the second interface sublayer 208 may be configured similar to the second sublayers. Hence, the first interface sublayer 206 and/or the second interface sublayer 208 may substantially consist of the (first) oxide of the first transition metal, the (second) oxide of the second transition metal, or of a mixture of the (first) oxide of the first transition metal and the (second) oxide of the second transition metal. As understood, the mixture of the (first) oxide of the first transition metal and the (second) oxide of the second transition metal may provide a mixed material. A stoichiometry of the mixed material the first and/or second interface sublayers substantially consist of may be different from a stoichiometry of the mixed material one or more of the second sublayers substantially consist of.

FIG. 2I shows an exemplary SPOC structure 120 similar to the one shown in FIG. 2D but differing in that the SPOC structure 120 includes the first interface sublayer 206 and the second interface sublayer 208. In this example, the first interface sublayer and the second interface sublayer may substantially consist of hafnium oxide (HfO₂). This may further reduce the overall concentration of ZrO₂ within the memory element 124 (e.g., below 60 at. %).

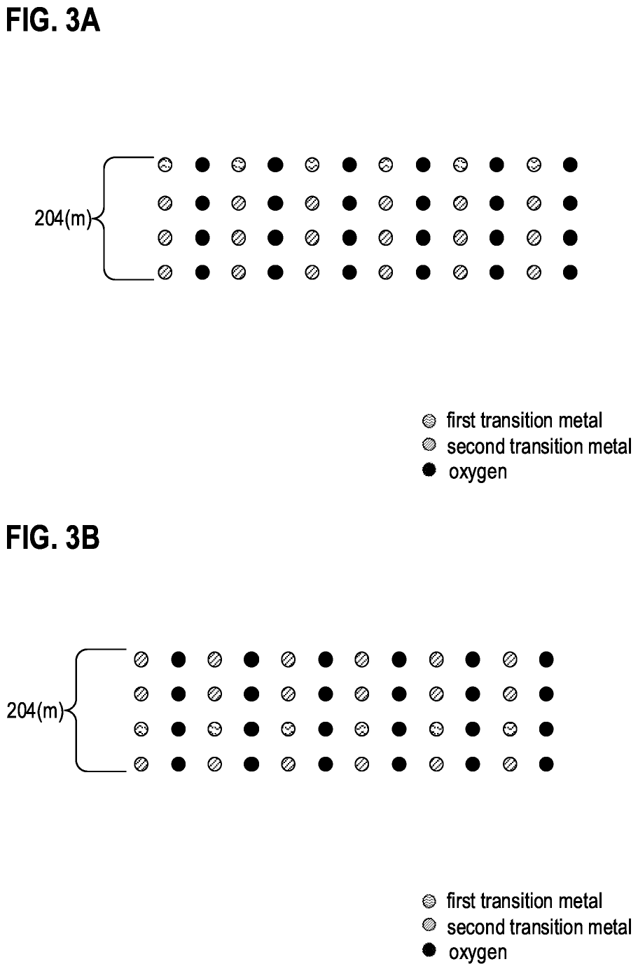

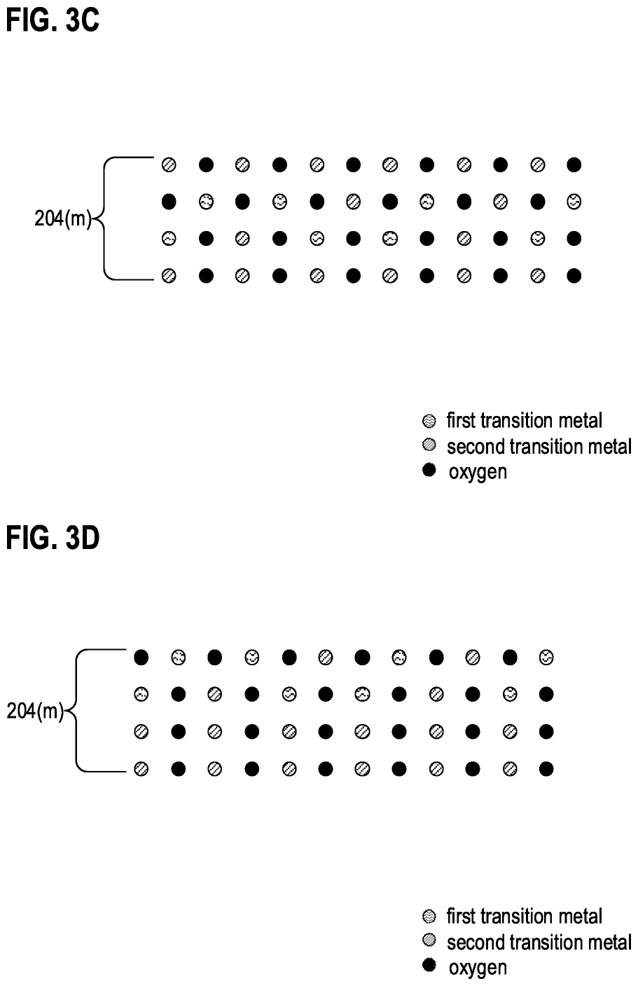

A composition of a sublayer (e.g., a first sublayer 202(n) and/or a second sublayer 204(m)), a concentration of one or more materials within the sublayer, a composition of the spontaneously polarizable memory layer stack, and/or a concentration of one or more materials within the spontaneously polarizable memory layer stack may be determined with techniques known in the art. For example, energy-dispersive X-ray spectroscopy (EDS) (e.g., in combination with scanning electron microcopy (SEM) or transmission electron microscopy (TEM)), Rutherford backscattering spectrometry (RBS), and/or secondary ion mass spectrometry (SIMS) may be used to analyze the composition and/or concentration. However, the composition of the sublayer, the concentration of the one or more materials within the sublayer, the composition of the spontaneously polarizable memory layer stack, and/or the concentration of the one or more materials within the spontaneously polarizable memory layer stack may be also apparent from a manufacturing protocol for manufacturing the spontaneously polarizable memory layer stack. For example, the plurality of sublayers of the spontaneously polarizable memory layer stack may be manufactured by means of deposition, such as atomic layer deposition (ALD) and the respective composition and/or concentration may be directly apparent from the used deposition protocol (e.g., the used ALD deposition protocol). As an illustrative example, a (e.g., each) second sublayer 204(m) of the second set 204(m=1 to M) may have a ratio between the second transition metal (e.g., Hf in the case of Hf_{0.75}Zr_{0.25}O₂) and the first transition metal (e.g., Zr in the case of Hf_{0.75}Zr_{0.25}O₂) of about 3 to 1. It is understood that there may be concentration variations which may change the ratio of about 3:1 slightly (see Hf_{0.75±ε}Zr_{0.25±τ}O_{2±δ}). This ratio may be achieved by (one or more sub-cycles of) depositing three atomic layers of the (second) oxide of the second transition metal and one atomic layer of the (first) oxide of the first transition metal independent of the order (see, for example, FIG. 3A and FIG. 3B). The ratio of 3:1 may also be achieved by (one or more sub-cycles of) depositing two atomic layers of the oxide of the second transition metal and two atomic layers of the oxide of both, the first transition metal and the second transition metal, independent of the order (see, for example, FIG. 3C and FIG. 3D). Hence, these examples show illustratively that the composition of a sublayer (e.g., a second sublayer 204(m)) and, hence, the concentration of a respective material within the sublayer can be determined based on the (e.g., ALD) deposition protocol used for manufacturing the sublayer. An atomic layer of the oxide of a transition metal may be deposited by a precursor pulse of the transition metal, a purging, and a subsequent pulse of an oxidizer to oxide the transition metal, as an example. A sublayer composition may also depend on a pulse time of the respective precursor pulse. For further details regarding ALD see description with reference to FIG. 6.

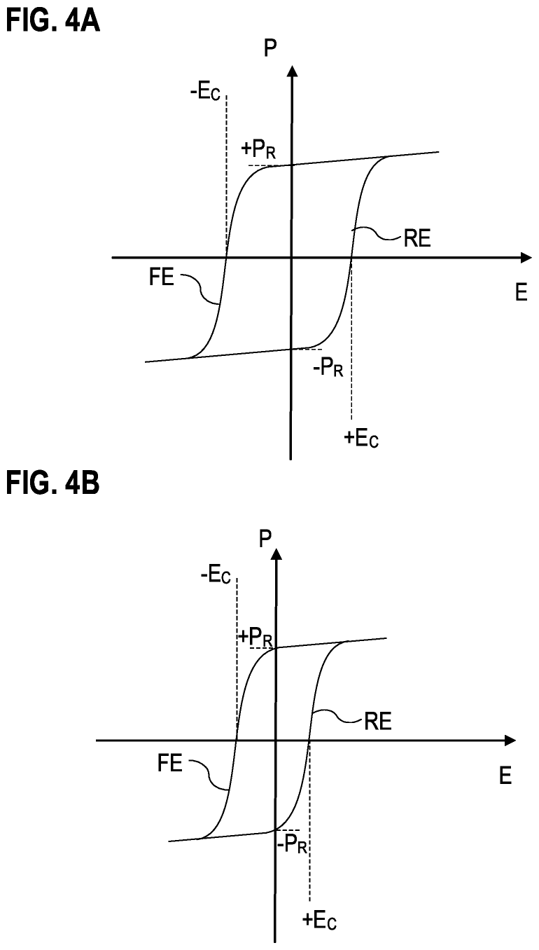

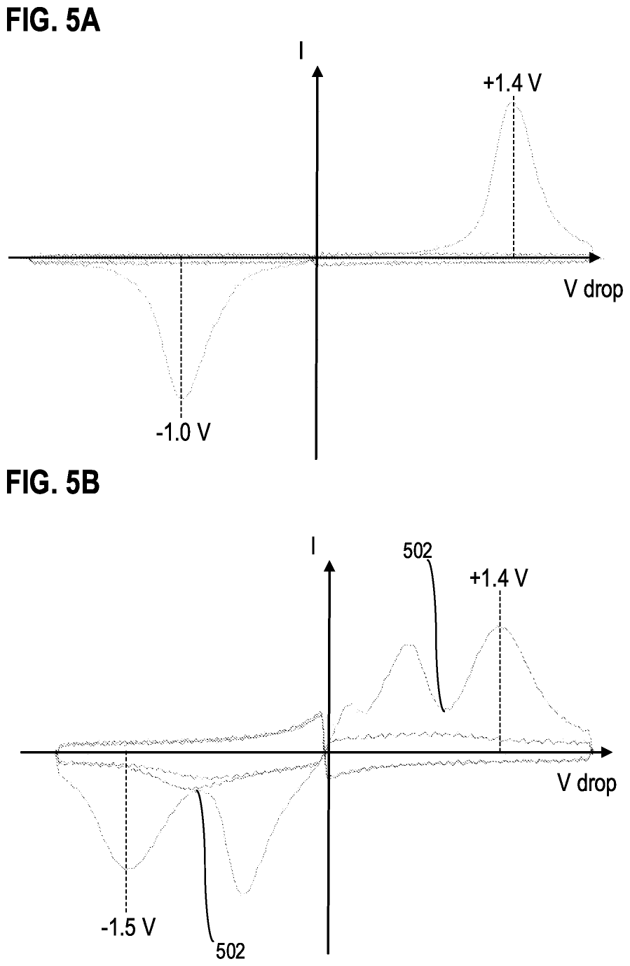

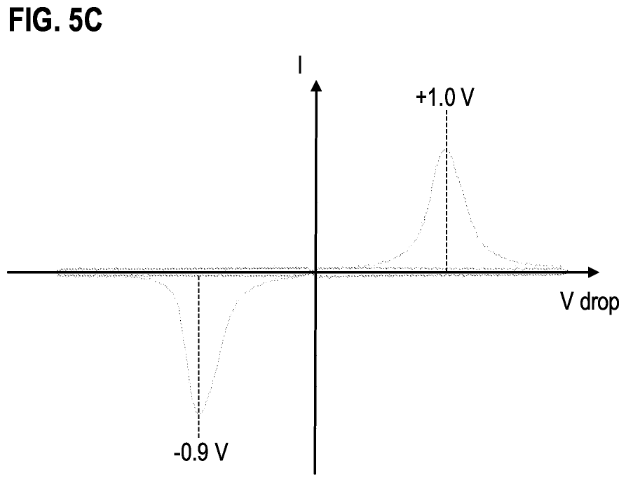

As described, the alternating sequence of first sublayers and second sublayers may start with a first sublayer 202(1) of the first set 202(n=1 to N) and may end with another first sublayer 202(n=N) of the first set 202(n=1 to N), thereby providing symmetry of the spontaneously polarizable memory layer stack. Alternatively or additionally, the second concentration of the second transition metal may be substantially more than the first concentration of the first transition metal within each second sublayer 204(m) of the second set 204(m=1 to M). In the following, various effects and advantages of these configurations are described with reference to FIG. 4A, FIG. 4B, FIG. 5A, FIG. 5B, and FIG. 5C:

FIG. 4A shows an exemplary polarization/electric field (P/E) characteristic (in some aspects referred to as polarization vs. electric field hysteresis loop, short polarization/electric field (P/E) hysteresis). This may apply similarly to polarization/voltage (P/V) characteristics. A P/E characteristic may be characterized by an electric coercive field E_{C} (with a negative coercive field −E_{C} and a positive coercive field +E_{C}), a (e.g., maximum) remanent polarization P_{R} (with a negative remanent polarization −P_{R} and a positive remanent polarization +P_{R}), a slope of the rising edge (RE), and a slope of the falling edge (FE). The P/E characteristic shown in FIG. 4A may refer to configuration of the spontaneously polarizable memory layer stack with M=N (see, for example, FIG. 2E), such that the spontaneously polarizable memory layer stack ends with a second sublayer 204(m=N). In comparison, FIG. 4B shows an exemplary P/E characteristic for a configuration of the spontaneously polarizable memory layer stack with M=N−1 (see, for example, FIG. 2A to FIG. 2D, FIG. 2F to FIG. 2I), such that the spontaneously polarizable memory layer stack ends with a first sublayer 202(n=N). As described herein, this configuration, with M=N−1, may lead to a symmetric spontaneously polarizable memory layer stack (e.g., a spontaneously polarizable memory layer stack having symmetric interfaces to the first electrode 126 and the second electrode 128). The symmetry of the spontaneously polarizable memory layer stack may be increased if each first sublayer 202(n) of the first set 202(n=1 to N) has the same thickness and/or if each second sublayer 204(m) of the second set 204(m=1 to M) has the same thickness. The symmetry of the spontaneously polarizable memory layer stack may be increased if each first sublayer 202(n) of the first set 202(n=1 to N) has the same composition and/or if each second sublayer 204(m) of the second set 204(m=1 to M) has the same composition. As shown in FIG. 4B, this symmetry may decrease the electric coercive field E_{C} (e.g., the negative coercive field −E_{C} and/or the positive coercive field +E_{C}). The higher electric coercive field E_{C} of the non-symmetric spontaneously polarizable memory layer stack (with M=N), shown in FIG. 4A, as compared to the electric coercive field E_{C} of the symmetric spontaneously polarizable memory layer stack (with M=N−1), shown in FIG. 4B, may be due to an initial imprint (in some aspects referred to as initial imprint effect). The initial imprint effect leads to a shift of the electric coercive field (e.g., in one direction). The same applies to the voltage in the case of a P/V characteristic such that after a first voltage pulse, a second voltage pulse having the same voltage value as the first voltage pulse might not be enough to read a memory state of the memory cell which includes the SPOC structure 120.

It is found that, in the case that the first concentration of the first transition metal and the second concentration of the second transition metal within each second sublayer 204(m) of the second set 204(m=1 to M) are substantially the same, the SPOC structure 120 may have a pinched P/E or P/V hysteresis loop at elevated temperatures (e.g., at temperatures higher than about 50° C., e.g., at an operation temperature at about 85° C.). Further, it is found that, in the case that the second concentration of the second transition metal is substantially more (e.g., substantially greater) than the first concentration of the first transition metal within each second sublayer 204(m) of the second set 204(m=1 to M), the SPOC structure 120 may have no pinched P/E or P/V hysteresis loop at elevated temperatures (e.g., at temperatures higher than about 50° C., e.g., at an operation temperature at about 85° C.).

For illustration, in FIG. 5A to FIG. 5C, a non-symmetric (with M=N according to FIG. 2E) first exemplary configuration of the spontaneously polarizable memory layer stack in which each second sublayer 204(m) of the second set 204(m=1 to M) substantially consists of Hf_{0.5} Zr_{0.5} O₂ is compared to a symmetric (with M=N−1 according to FIG. 2A) second exemplary configuration of the spontaneously polarizable memory layer stack in which each second sublayer 204(m) of the second set 204(m=1 to M) substantially consists of Hf_{0.75} Zr_{0.25}O₂ (e.g., Hf_{0.75±ε}Zr_{0.25±τ}O_{2+δ} as described above). Here, the second concentration of the second transition metal, Hf, is substantially more than the first concentration of the first transition metal, Zr). In both, the first exemplary configuration and the second exemplary configuration, each first sublayer 202(n) of the first set 202(n=1 to N) may substantially consists of ZrO₂.

FIG. 5A shows an I/V characteristic of the first exemplary configuration measured at 25° C. showing a respective current peak (which may be employed to read a memory cell including the SPOC structure) at −1 V and at +1.4 V. FIG. 5B shows an I/V characteristic of the first exemplary configuration measured at 85° C. (which may be an operating temperature of the memory cell including the SPOC structure) showing a respective current peak (which may be employed to read the memory cell including the SPOC structure) at −1.5 V and at +1.4 V. FIG. 5B also shows the pinching of the curve at pinching points 502. FIG. 5C shows an I/V characteristic of the second exemplary configuration measured at 85° C. (which may be an operating temperature of the memory cell including the SPOC structure) showing a shift of the current peaks to lower (absolute) voltage values (e.g., due to the symmetric interfaces) as well as no pinching behavior. Each of the cycles to obtain the I/V characteristics of FIG. 5A to FIG. 5C are measured between −2 V and +2 V at 100 kHz.

Hence, it is shown that the content of the first transition metal can cause a pinched hysteresis loop at elevated temperatures (e.g., at the operation temperature of about 85° C.). This may be caused in the case that a Curie temperature of the (first) oxide of the first transition metal is lower than a Curie temperature of the (second) oxide of the second transition metal which may lead to a partial polar to non-polar phase transition in the (e.g., ferroelectric) spontaneously polarizable memory layer stack. The fraction of the non-polar phase may define the level of pinching. Thus, decreasing the content of the first transition metal within the spontaneously polarizable memory layer stack may increase the Curie temperature of the spontaneously polarizable memory layer stack (e.g., above the operating temperature of about 85° C.), thereby removing the pinching behavior.

Further it is shown that the symmetric interfaces to first electrode 126 and the second electrode 128 may reduce a read voltage required to read out the memory cell including the SPOC structure 120. An operation of a (e.g., sub-10 nm) Hf₁₋ₓZrₓO₂-based memory cell at a relatively high voltage (e.g., at voltage values greater than 2.5 V) yields a limited endurance due to the large electrical stress after each read and write pulse. On the other hand, an operation of the Hf₁₋ₓZrₓO₂-based memory cell at low voltage values causes a limited retention and/or fatigue. Therefore, using an optimum voltage might be a fast solution to meet both, endurance criteria and retention criteria. However, the electric coercive field imposes a lower limit for the operation. Therefore, reducing the electric coercive field by using the symmetric interfaces, described herein, may allow to manufacture a memory cell arrangement including memory cells which meet both of the above criteria, namely the endurance criteria and the retention criteria.

Therefore, the performance of each memory cell of a memory cell arrangement may be increased by using the alternating sequence of first sublayers and second sublayers having the symmetric interfaces and/or by using second sublayers having a second concentration of the second transition metal substantially greater than a first concentration of the first transition metal.

As described, the spontaneously polarizable memory layer stack may be disposed between the first electrode 126 (in some aspects referred to as bottom electrode) and the second electrode 128 (in some aspects referred to as top electrode). A material of the first electrode 126 and/or of the second electrode 128 may have an electrical conductivity greater than 10⁶ S/m at a temperature of 20° C. The first electrode 126 and/or the second electrode 128 may have a thickness less than 10 nm, for example less than 5 nm, for example less than 2 nm. The coefficient of thermal expansion of the first electrode 126 and/or the second electrode 128 may be below 7 ppm. The first electrode 126 and/or the second electrode 128 may include or may consist of a metal, such as Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Aluminum (Al), Gold (Au), Cobalt (Co), tungsten (W).

The first electrode 126 and/or the second electrode 128 may include or may consist of a metal nitride. The metal nitride may be, for example, a titanium-based alloy (e.g., TiN, e.g., Ti—C—N, e.g., Ti—Al—N, e.g., TiN—TaN) or tantalum-based alloy (e.g., TaN, e.g., Ta—C—N, e.g., TaN—TiN).

The first electrode 126 and/or the second electrode 128 may include or may consist of an oxidation resistant metal (e.g., a noble metal). The oxidation resistant metal may have an electronegativity greater than 1.85 on the Pauling scale. The oxidation resistant metal may have a melting temperature greater than 1450° C. This may reduce an oxidation of the interface of the respective electrically conductive electrode layer. The oxidation resistant metal may include (e.g., consist of), for example, tungsten, platinum, iridium, ruthenium, palladium, osmium, rhodium, molybdenum, cobalt, rhenium, or nickel. According to various aspects, the first electrode 126 and/or the second electrode 128 may have a work function of the oxidation resistant metal equal to or greater than 5 eV. According to various aspects, using oxidation resistant metal electrode(s) in combination with a spontaneously polarizable material which includes transition-metal-oxides (e.g., as a high-k capacitor dielectric) may suppress a charge injection due to the work function equal to or greater than 5 eV and a comparatively high band-offset. The band-offset may be a conduction band-offset for electrons (between Fermi-level of the electrode and the conduction band of the dielectric layers) or a valance band offset for holes (between Fermi-level of the electrode and the valence band of the dielectric layers).

The first electrode 126 and/or the second electrode 128 may include or may consist of a metal oxide, such as tungsten oxide.

A spontaneously polarizable material (e.g., HZO) of the spontaneously polarizable memory layer stack may exhibit the spontaneously polarizable properties only in the crystalline phase. According to some aspects, the spontaneously polarizable material may be deposited already in the crystallized state. According to other aspects, the spontaneously polarizable material may be deposited substantially amorphous and crystallized afterwards. Hence, herein the material of the memory element 124 may be referred to as spontaneously polarizable material even in the amorphous state prior to exhibiting the spontaneously polarizable properties responsive to crystallization.

The spontaneously polarizable material (e.g., HZO) of the memory element 124 may be crystallized by annealing (e.g., thermally annealing). The annealing may include a furnace annealing, a flash-lamp annealing, and/or a laser annealing. The annealing may be carried out in an inert gas atmosphere (e.g., nitrogen, e.g., argon) at any suitable pressure, e.g., at atmospheric pressure, at a pressure below atmospheric pressure, or at a pressure above atmospheric pressure. In some aspects, the annealing may be carried out in a vacuum. A vacuum in a processing chamber (e.g., for depositing a material and/or for annealing a material) may be provided in a pressure range below 50 mbar. According to various aspects, the memory element 124 may be annealed using a laser annealing and/or a flash-lamp annealing with local temperatures in the range from about 1500° C. to about 1850° C. The local temperatures in the range from about 1500° C. to about 1850° C. may result in homologous temperature, TH, of the capacitive memory structure given by a temperature, T, over a melting temperature of the one or more transition-metal-oxides, Tₘₑₗₜ, in the range from about 0.6 to about 0.7 or greater than 0.7. For example, it may be possible to crystallize the HZO into the ferroelectric phase by annealing at temperatures in a range from about 300° C. to about 400° C. The crystallized spontaneously polarizable material may be polycrystalline including a plurality of crystallites and the crystallites may have the predefined crystallographic texture, as achieved by means of the amorphous functional layer(s). As an example, a majority of the crystallites (e.g., at least 50%, e.g., at least 75%, e.g., at least 90% of the crystallites) may be oriented along the same direction and therefore define a crystallographic texture. The term “texture”, as used herein, may describe a crystallographic texture as a property of a material or of a layer including a material. The crystallographic texture may be related to a distribution of crystallographic orientations of crystallites of a polycrystalline material. The crystallographic texture may be described by an orientation distribution function (ODF). A crystallographic texture of a layer, as referred to herein, may describe a preferred orientation of the crystallites of a polycrystalline material with reference to a surface of the layer. A crystallographic texture of a layer, as referred to herein, may describe a preferred orientation of the crystallites of a polycrystalline material with reference a direction of an external electric field caused by a voltage applied to electrodes contacting the layer. In other words, a material or layer consisting of crystallites may have no texture in the case that the orientations of the crystallites are randomly distributed. The material or layer may be regarded as a textured material or layer in the case that the orientations of the crystallites show one or more preferred directions. For example, a (001)-texture of the spontaneously polarizable memory layer may describe that most of the crystallites of the polycrystalline material that forms at least part of the spontaneously polarizable memory layer are oriented with their (001)-lattice planes along a direction perpendicular to the (e.g., upper) surface of the spontaneously polarizable memory layer. For example, a (001)-texture of the spontaneously polarizable material of the memory element 124 may describe that most of the crystallites of the polycrystalline material that forms at least part of the spontaneously polarizable material are oriented with their (001)-lattice planes along a direction perpendicular to a growth direction associated with the spontaneously polarizable material. As another example, a (111)-texture of the spontaneously polarizable material of the memory element 124 may describe that most of the crystallites of the polycrystalline material that forms at least part of the spontaneously polarizable material are oriented with their (111)-lattice planes along a direction perpendicular to the (e.g., upper) surface of the spontaneously polarizable material. For example, a (111)-texture of the spontaneously polarizable material may describe that most of the crystallites of the polycrystalline material that forms at least part of the spontaneously polarizable memory layer are oriented with their (111)-lattice planes along a direction perpendicular to a growth direction associated with the spontaneously polarizable memory layer. The (001)-texture may be a (001)-fiber-texture or a (001)-biaxial-texture. The (111)-texture may be a (111)-fiber-texture or a (111)-biaxial-texture. In general, the crystallographic texture may be described by the orientation distribution function (ODF), wherein x-ray diffraction patterns (e.g., pole-figure measurements, e.g., theta-2theta x-ray diffraction measurements with a scattering vector in plane-normal direction, such as perpendicular to a surface of electrodes of a planar capacitive memory structure) or other suitable measurements, e.g., based on transmission electron microscopy, electron backscatter diffraction (EBSD), or transmission Kikuchi diffraction (TKD), may be used to determine the orientation of the crystalline grains of the material.

FIG. 6 shows a flow diagram of a method 600 for processing (e.g., manufacturing) a memory capacitor (e.g., a SPOC structure 120 having one of the configurations described herein).

The method 600 may include forming a first electrode layer (in 602). The first electrode layer may be formed at least one of over or in a substrate. In some aspects, the substrate may include or may be a silicon substrate e.g., with or without a (e.g., native) SiO₂ surface layer, or any other suitable semiconductor substrate. In other aspects, the substrate may include or may be an electrically non-conductive substrate, e.g., a glass substrate. In still other aspects, the substrate may include or may be an electrically conductive substrate, e.g., a metal substrate. The first electrode layer may an electrically conductive electrode layer. The first electrode layer may provide at least part of the first electrode 126 of the SPOC structure 120. The first electrode layer may be formed by vapor deposition. The vapor deposition may be a physical vapor deposition (PVD), such as sputtering, or chemical vapor deposition (CDV), such as atomic layer deposition (ALD).

The method 600 may include forming a spontaneously polarizable memory layer stack over the first electrode layer (in 604). Forming the spontaneously polarizable memory layer stack may include forming an alternating sequence of first sublayers and second sublayers. Each of the second sublayers may include (e.g., may substantially consist of) an (first) oxide of a first transition metal and an (second) oxide of a second transition metal. Each of the first sublayers may substantially consist of the (first) oxide of the first transition metal or the (second) oxide of the second transition metal. According to an example, all first sublayers may substantially consist of the (first) oxide of the first transition metal or may, alternatively, substantially consist of the (second) oxide of the second transition metal. According to another example, one or more of the first sublayers may substantially consist of the (first) oxide of the first transition metal and the other first sublayers may substantially consist of the (second) oxide of the second transition metal.

The method 600 may include that forming an alternating sequence of first sublayers and second sublayers includes forming the alternating sequence of first sublayers and second sublayers starting with one of the first sublayers and ending with another one of the first sublayers (in 604A). Alternatively or additionally, the method 600 may include that the mixed material includes a first concentration of the first transition metal and a second concentration of the second transition metal which is substantially different from (e.g., substantially more than) the first concentration of the first transition metal (in 604B).

Optionally, the method 600 may include forming a first interface sublayer (e.g., in direct physical contact with the first electrode layer) prior to forming the alternating sequence of first sublayers and second sublayers. The first interface sublayer may substantially consist of the (first) oxide of the first transition metal, the (second) oxide of the second transition metal, or a mixture of the (first) oxide of the first transition metal and the (second) oxide of the second transition metal (see, for example, the description with reference to the first interface sublayer 206).

The method 600 may include forming a second electrode layer over the spontaneously polarizable memory layer stack (in 606). The first electrode layer may be formed by vapor deposition (e.g., by physical vapor deposition (PVD), such as sputtering, or by chemical vapor deposition (CDV), such as atomic layer deposition (ALD)).

Optionally, the method 600 may include forming a second interface sublayer prior to forming the second electrode layer (e.g., the second electrode layer may be in direct physical contact with the second interface sublayer). The second interface sublayer may substantially consist of the (first) oxide of the first transition metal, the (second) oxide of the second transition metal, or a mixture of the (first) oxide of the first transition metal and the (second) oxide of the second transition metal (see, for example, the description with reference to the second interface sublayer 208).

According to various aspects, the forming the alternating sequence may include forming (e.g., depositing) the first sublayers and/or the second sublayers via atomic layer deposition (ALD). For example, both, the first sublayers and the second sublayers may be formed via atomic layer deposition (ALD) such that the alternating sequence is formed by ALD. The first interface sublayer and/or the second interface sublayer may be formed by ALD. In the following, various aspects regarding an ALD of the first sublayers and the second sublayers is described which may apply analogously to the first interface sublayer and the second interface sublayer:

In general, an atomic layer deposition of a sublayer (e.g., one of the first sublayers and/or one of the second sublayers) may include various cycles and/or sub-cycles. An atomic layer of a sublayer, which includes an oxide, may be formed by a respective precursor pulse of one or more materials (e.g., the first transition metal and/or the second transition metal) and a pulse of an oxidizer (in some aspects referred to as oxidizer pulse) to oxidize the one or more materials. A precursor pulse may be associated with injecting a gas which includes the respective material of the one or more materials (or which includes oxygen atoms in the case of the oxidizer pulse) into a processing chamber in which the memory capacitor is (or is to be) processed. A precursor pulse may be associated with a pulse time defining a time for which the gas is injected into the processing chamber. In some aspects, the pulse of an oxidizer may be referred to as precursor pulse of the oxidizer. A pulse of an oxidizer may include injecting a predefined concentration of the oxidizer (e.g. >200 g/m³) into the processing chamber. The oxidizer (in some aspects referred to as oxidizing agent) may include or may be O₃, H₂O, and/or O₂. For example, a respective pulse time of each pulse of an oxidizer may be in the range from about 1 second to about 30 seconds. Each pulse, described herein, may also be associated with a respective process temperature representing a temperature of the substrate and/or the already formed part of the memory capacitor. After each pulse (e.g., after a precursor pulse and/or after a pulse of an oxidizer), a respective purging may be carried out. Hence, for example, a purging may be carried out between a precursor pulse and a consecutive pulse of an oxidizer, or vice versa. A purging may include a purging of remaining gas associated with the respective pulse (e.g., precursor pulse or oxidizer pulse). The purging of the remaining gas may include a purging with another gas, such as nitrogen (N₂). Alternatively, such as in the case of spatial ALD, gas barriers (e.g., a N₂ barrier) may be used instead of purging. Thus, it is understood that between two consecutive pulses described herein (e.g., between a precursor pulse and an oxidizer pulse, or vice versa), a purging may be carried out and/or the substrate may be moved through a gas barrier (e.g., into another chamber).

Various cycles and/or sub-cycles, described herein, refer to the deposition and subsequent oxidation of a transition metal to form the oxide of the transition metal. This forming of the oxide of the transition metal (e.g., the (first) oxide of the first transition metal or the (second) oxide of the second transition metal), described herein, may refer to forming about 1 Å of the oxide of the transition metal. However, it is understood that the forming of the oxide of the transition metal may also refer to forming about 0.5 Å of the oxide of the transition metal; in this case, the number of cycles or sub-cycles may be doubled to form a layer having the same thickness as a layer formed using the about 1 Å oxide formation described above.

Various aspects refer to a precursor pulse of a transition metal. The precursor pulse of the transition metal may include injecting a precursor gas which includes the transition metal into the processing chamber. It is understood that the precursor gas may include other components as well; however, the precursor gas may be configured such that, at least after a purging, substantially only atoms of the transition metal are deposited at a surface of the processed memory capacitor. For example, the transition metal may be hafnium and the precursor gas may include hafnium, such as Tetrakis-(ethylmethylamido)-hafnium (TEMA-Hf) or Tetrakis-(dimethylamido)-hafnium (TDMA-Hf). For example, the transition metal may be zirconium and the precursor gas may include zirconium, such as Tetrakis-(ethylmethylamido)-zirconium (TEMA-Zr) or Tetrakis-(dimethylamido)-zirconium (TDMA-Zr). Any chemistry associated with the atomic layer deposition capable to remove ligands of the respective precursor may be used.

Various aspects refer to a pulse of an oxidizer. It is understood that a gas associated with the oxidizer may consist of oxygen atoms, such as O₂, or O₃, or may include other components as well, such as H₂O or H₂O₂.

According to various aspects, forming a respective first sublayer of the first sublayers may include one or more (first) cycles of ALD. In each cycle of the one or more (first) cycles, an atomic layer of the respective first sublayer may be formed. As described, the respective first sublayer may substantially consist of the (first) oxide of the first transition metal (or may alternatively substantially consist of the (second) oxide of the second transition metal). Each cycle of the one or more (first) cycles may include a precursor pulse of the first transition metal (or alternatively the second transition metal) and a pulse of an oxidizer. The pulse of the oxidizer may oxidize the first transition metal (or alternatively the second transition metal) to form the (first) oxide of the first transition metal (or alternatively the (second) oxide of the second transition metal). It is understood that forming the atomic layers of the respective first sublayer by a precursor pulse of a transition metal and a subsequent oxidizing of the transition metal by applying an oxidizer pulse leads to the fact that the respective first sublayer substantially consists of the oxide of the transition metal. As described herein, a purging (e.g., using N₂) may be carried out prior to and after the pulse of the oxidizer. It is understood that each pulse of an oxidizer, described herein, may be associated with the same oxidizer or at least one oxidizer pulse may be associated with an oxidizer different from the oxidizer of the other oxidizer pulses. A number of cycles of the one or more (first) cycles may define a thickness of the respective first sublayer (e.g., a desired thickness of about 6 Å). As described herein, each ALD cycle may be associated with forming about 1 Å or of about 0.5 Å of the oxide of the transition metal such that the thickness of the respective first sublayer may depend on the thickness per cycle and the number of cycles. Each of the first sublayers may be formed using the same one or more (first) ALD cycles.

According to various aspects, forming a respective second sublayer of the second sublayers may include one or more (second) cycles of ALD. A number of cycles of the one or more (second) cycles may define a thickness of the respective second sublayer (e.g., a desired thickness of about 8 Å). The one or more (second) cycles may be configured such that the respective second sublayer has a desired composition. The desired composition may include that the second concentration of the second transition metal is substantially different from (e.g., substantially more than) the first concentration of the first transition metal (see 604B).

The (desired) composition of the respective second sublayer may be achieved by forming each atomic layer of the respective second sublayer with the (desired) composition. For example, forming a respective atomic layer of the respective second sublayer may include a (first) precursor pulse of the first transition metal and (e.g., after purging) a (second) precursor pulse of the second transition metal and (e.g., after purging) a (third) pulse of an oxidizer to oxidize the first transition metal and the second transition metal. A ratio between a first pulse time of the (first) precursor pulse of the first transition metal and a second pulse time of the (second) precursor pulse of the second transition metal may define a concentration ratio between the first transition metal and the second transition metal within the respective atomic layer.

The (desired) composition of the respective second sublayer may be achieved by cycling a (e.g., island) deposition of the (first) oxide of the first transition metal and a (e.g., island) deposition of the (second) oxide of the second transition metal.

The (desired) composition of the respective second sublayer may be achieved by forming atomic layers which have different compositions; however, in total the respective composition of the atomic layers of the respective second sublayer may result in the (desired) composition.

As an example, each cycle of the one or more (second) cycles may include a first sub-cycle and at least two second sub-cycles (e.g., at least three sub-cycles (e.g., exactly three sub-cycles)). The first sub-cycle may include a precursor pulse of the first transition metal and a pulse of an oxidizer to oxidize the first transition metal. Thus, the first sub-cycle may form one or more (first) islands (or an atomic layer) of the (first) oxide of the first transition metal. Each second sub-cycle of the at least two second sub-cycles may include a precursor pulse of the second transition metal and a pulse of an oxidizer to oxidize the second transition metal. Thus, a respective second sub-cycle may form one or more islands (or an atomic layer) of the (second) oxide of the second transition metal. Hence, a number of second sub-cycles of the at least two second sub-cycles may define a composition of the respective second sublayer. For example, in the case that the at least two second sub-cycles include exactly two sub-cycles, the respective second sublayers may include one atomic layer of the (first) oxide of the first transition metal and two atomic layers of the (second) oxide of the second transition metal. In this case, the second concentration of the second transition metal may be twice the first concentration of the first transition metal. In another example, in the case that the at least two second sub-cycles include three sub-cycles, the respective second sublayers includes one atomic layer of the (first) oxide of the first transition metal and three atomic layers of the (second) oxide of the second transition metal. In this case, the second concentration of the second transition metal may be three-times the first concentration of the first transition metal. For example, in the case that the first transition metal is zirconium and that the second transition metal is hafnium, using three second sub-cycles may result in a composition of the respective second sublayer of about Hf_{0.75±ε}Zr_{0.25±τ}O_{2±δ} (see, for example, FIG. 2D). The first sub-cycle and the second sub-cycles of the at least two second sub-cycles may be carried out in any order. For example, the first sub-cycle may be carried out prior to or after the at least two second sub-cycles (see, for example, FIG. 3A). According to another example, the first sub-cycle may be carried out between two second sub-cycles of the at least two second sub-cycles (see, for example, FIG. 3B). As illustratively shown, the second concentration of the second transition metal may be substantially more than the first concentration of the first transition metal. This kind of sub-cycling the (first) oxide of the first transition metal (e.g., via island deposition) and sub-cycling the (second) oxide of the second transition metal (e.g., via island deposition) may ensure a mixture of the (first) oxide of the first transition metal and the (second) oxide of the second transition metal within the respective second sublayer. For illustration, the forming (e.g., deposition) of the alternating sequence of first sublayers and second sublayers (of the spontaneously polarizable memory layer stack), which starts with one of the first sublayers and ends with another one of the first sublayers (see 604A) and in which each of the second sublayers includes that the second concentration of the second transition metal is substantially more than the first concentration of the first transition metal (see 604B), may be described by the formula:

L₁*(L₂*(ZPOP)+L₃*(HPOP HPOP HPOP ZPOP))+L₂*(ZPOP),

wherein:
“Z” indicates a precursor pulse of the first transition metal (e.g., Zr),
“H” indicates a precursor pulse of the second transition metal (e.g., Hf),
“O” indicates a pulse of an oxidizer (e.g., O₂, O₃, H₂O or H₂O₂),
“P” indicates a purging (e.g., using N₂).

Hence, “ZPOP” may indicate a deposition of an atomic layer of the (first) oxide of the first transition metal (e.g., ZrO₂) and “HPOP” may indicate a deposition of an atomic layer of the (second) oxide of the second transition metal (e.g., HfO₂). As described above, the order of “HPOP” and “ZPOP” within the term “HPOP HPOP HPOP ZPOP” may be changed. “L₂” may indicate a (first) number of sub-cycling the (first) oxide of the first transition metal within a respective first sublayer and “L₃” may indicate a (second) number of repetitions of “HPOP HPOP HPOP ZPOP”. Thus, L₂*(ZPOP) may indicate a first sublayer and L₃*(HPOP HPOP HPOP ZPOP) may indicate a second sublayer. “L₁” may indicate a number of repetitions in which each repetition includes a first sublayer and a second sublayer. As an example, in the case of L₁=7, L₂=6, and L₃=2, a spontaneously polarizable memory layer stack having a thickness of about 10 nm may be formed. In the case that a respective second sublayer substantially consists of Hf_{0.75±ε}Zr_{0.25±τ}O_{2±δ}, a thickness of about 5 Å may be required to form a unit cell. It may be required to form at least one unit cell to ensure a closed layer of the respective second sublayer. Therefore, in order that the respective second sublayer has a thickness of at least 5 Å: L₃ may equal to or greater than two in the case that each deposition is associated with about 1 Å and L₃ may equal to or greater than three in the case that each deposition is associated with about 0.5 Å.

As described herein, the first sublayer 202(1) closest to the first electrode 126 and the first sublayer 202(n=N) closest to the second electrode may substantially consist of the (second) oxide of the second transition metal and all other first sublayers 202(n=2 to N−1) may substantially consist of the (first) oxide of the first transition metal. This may be described by the formula:

L₄*(HPOP)+L₁*(L₃*(HPOP HPOP HPOP ZPOP)+L₂*(ZPOP))+L₃*(HPOP HPOP HPOP ZPOP)+L₄*(HPOP),

wherein “L₄” may indicate a number of sub-cycling the (second) oxide of the second transition metal (e.g., of sub-cycling HfO₂). As an example, a spontaneously polarizable memory layer stack having a thickness of about 10 nm may be formed in the case of L₁=6, L₂=6, L₃=2, and L₄=6.

As another example, each cycle of the one or more (second) cycles may include one or more first sub-cycles and one or more second sub-cycles. Each second sub-cycle of the one or more second sub-cycles may include a precursor pulse of the second transition metal and a pulse of an oxidizer to oxidize the second transition metal. Thus, a respective second sub-cycle may form an atomic layer of the (second) oxide of the second transition metal. A respective first sub-cycle of the one or more first sub-cycles may include a (first) precursor pulse of the first transition metal and a (second) precursor pulse of the second transition metal and a (third) pulse of an oxidizer to oxidize the first transition metal and the second transition metal. A ratio between a first pulse time of the (first) precursor pulse of the first transition metal and a second pulse time of the (second) precursor pulse of the second transition metal may define a concentration ratio between the first transition metal and the second transition metal within the respective atomic layer. As an example, the first pulse time may correspond to the second pulse time such that the respective first sub-cycles results in an atomic layer having the same concentration of the first transition metal and the second transition metal. For example, in the case that the first transition metal is zirconium and that the second transition metal is hafnium, the respective first sub-cycle may result in an atomic layer having composition of about Hf_{0.5} Zr_{0.5}O₂. A ratio between a first number of first sub-cycles of the one or more first sub-cycles and a second number of second sub-cycles of the one or more second sub-cycles may define a composition the respective second sublayer. For example, each cycle of the one or more (second) cycles may include two first sub-cycles to form atomic layers in which the first concentration of the first transition metal is substantially equal to the second concentration of the second transition metal and two second sub-cycles to form atomic layers which substantially consist of the (second) oxide of the second transition metal. This may result in a second sublayer in which the second concentration of the second transition metal is three times (and hence substantially more) the first concentration of the first transition metal. The first sub-cycles of the one or more first sub-cycles and the second sub-cycles of the one or more second sub-cycles may be carried out in any order. According to an example, the one or more first sub-cycles may be carried out after the one or more second sub-cycles (see, for example, FIG. 3D). According to another example, at least one of the one or more first sub-cycles may be carried out between two second sub-cycles (see, for example, FIG. 3C). As illustratively shown, the second concentration of the second transition metal within the respective second sublayer may be substantially more than the first concentration of the first transition metal. Forming at least some atomic layers of the respective second sublayer may allow to tune the content of the first transition metal with less restrictions on the thickness of the respective second sublayer.

As described herein, the memory element 124 may include the first interface sublayer 206 and the second interface sublayer 208. The first interface sublayer 206 may be disposed between the first electrode layer 126 and spontaneously polarizable memory layer stack and the second interface layer 208 may be disposed between spontaneously polarizable memory layer stack and the second electrode 128. In the case that all first sublayers substantially consist of the (first) oxide of the first transition metal and that the first interface sublayer 206 and the second interface sublayer 208 substantially consist of the (second) oxide of the second transition metal, forming the memory element 124 may be describe by formula:

L₅*(HPOP)+L₁*(L₂*(ZPOP)+L₃*(HPOP HPOP HPOP ZPOP))+L₂*(ZPOP)+L₅*(HPOP),

wherein “L₅” may indicate a number of sub-cycling the (second) oxide of the second transition metal (e.g., of sub-cycling HfO₂). Hence, the term L₅*(HPOP) may refer to the respective interface sublayer.

In the following, various examples are provided that may include one or more aspects described above with reference to a memory cell including the SPOC structure 120, a memory capacitor layer stack including the SPOC structure 120, and the method 600. It may be intended that aspects described in relation to the method 600 may apply also to the memory cell and the memory capacitor layer stack, and vice versa. For example, the method 600 may include at least a part of the formation of the SPOC structure 120.

Example 1 is a memory cell including: a first electrode; a second electrode; and a memory element disposed between the first electrode and the second electrode, the first electrode, the second electrode, and the memory element forming a memory capacitor; wherein the memory element includes a spontaneously polarizable memory layer stack, the spontaneously polarizable memory layer stack including an alternating sequence of first sublayers and second sublayers starting with one of the first sublayers and ending with another one of the first sublayers, wherein each of the second sublayers includes (e.g., substantially consists of) an oxide of a first transition metal and an oxide of a second transition metal and wherein each of the first sublayers substantially consists of the oxide of the first transition metal.

In Example 2, the subject matter of Example 1 can optionally include that each of the second sublayers includes (e.g., consists of) a first concentration of the first transition metal and a second concentration of the second transition metal which is substantially more than the first concentration of the first transition metal.

Example 3 is a memory cell including: a first electrode; a second electrode; and a memory element disposed between the first electrode and the second electrode, the first electrode, the second electrode, and the memory element forming a memory capacitor; wherein the memory element includes a spontaneously polarizable memory layer stack, the spontaneously polarizable memory layer stack including an alternating sequence of first sublayers and second sublayers, wherein each of the second sublayers includes an oxide of a first transition metal and an oxide of a second transition metal, wherein each of the first sublayers substantially consists of the oxide of the first transition metal, and wherein each of the second sublayers includes a first concentration of the first transition metal and a second concentration of the second transition metal which is substantially more than the first concentration of the first transition metal.

In Example 4, the subject matter of Example 3 can optionally include that the alternating sequence of the first sublayers and the second sublayers starts with one of the first sublayers and ends with another one of the first sublayers.

In Example 5, the subject matter of any one of Examples 1 to 4 can optionally include that the spontaneously polarizable memory layer stack includes an odd number of second sublayers.

Example 6 is a memory cell including: a first electrode; a second electrode; and a memory element disposed between the first electrode and the second electrode, the first electrode, the second electrode, and the memory element forming a memory capacitor; wherein the memory element includes a spontaneously polarizable memory layer stack, the spontaneously polarizable memory layer stack including an odd number of sublayers, wherein the sublayers include an alternating sequence of first sublayers and second sublayers, wherein each of the second sublayers includes (e.g., consists of) an oxide of a first transition metal and an oxide of a second transition metal and wherein each of the first sublayers substantially consists of the oxide of the first transition metal.

In Example 7, the subject matter of Example 6 can optionally include that each of the second sublayers includes (e.g., consists of) a first concentration of the first transition metal and a second concentration of the second transition metal, wherein the second concentration of the second transition metal is substantially more than the first concentration of the first transition metal.

In Example 8, the subject matter of Example 6 or 7 can optionally include that the alternating sequence of the first sublayers and the second sublayers starts with one of the first sublayers and ends with another one of the first sublayers.

In Example 9, the subject matter of any one of Examples 1 to 8, provided that in combination with Example 1, 4, or 8, can optionally include that the one of the first sublayers with which the alternating sequence of first sublayers and second sublayers starts is disposed in direct physical contact with the first electrode.

In Example 10, the subject matter of any one of Examples 1 to 9, provided that in combination with Example 1, 4, or 8, can optionally include that the other one of the first sublayers with which the alternating sequence of first sublayers and second sublayers ends is disposed in direct physical contact with the second electrode

In Example 11, the subject matter of any one of Examples 1 to 10, provided that in combination with Example 1, 4, or 8, can optionally include that the one of the first sublayers with which the alternating sequence of first sublayers and second sublayers starts and the other one of the first sublayers with which the alternating sequence of first sublayers and second sublayers ends have the same thickness.

In Example 12, the subject matter of any one of Examples 1 to 11, provided that in combination with Example 2, 3, or 7, can optionally include that, the second concentration being substantially more than the first concentration includes that the second concentration of the second transition metal is at least 1.5-times the first concentration of the first transition metal.

In Example 13, the subject matter of any one of Examples 1 to 12, provided that in combination with Example 2, 3, or 7, can optionally include that, the second concentration being substantially more than the first concentration includes that the second concentration of the second transition metal is at least twice the first concentration of the first transition metal.

In Example 14, the subject matter of any one of Examples 1 to 13, provided that in combination with Example 2, 3, or 7, can optionally include that, the second concentration being substantially more than the first concentration includes that a concentration of the oxide of the second transition metal within each of the second sublayers is equal to or greater than 70 at. % (e.g., equal to or greater than 75 at. %).

In Example 15, the subject matter of any one of Examples 1 to 14, provided that in combination with Example 2, 3, or 7, can optionally include that, the second concentration being substantially more than the first concentration of each of the second sublayers includes that the second sublayers include on average a concentration of the oxide of the second transition metal of equal to or greater than 60 at. % (e.g., equal to or greater than 75 at. %, e.g., equal to or greater than 75 at. %).

In Example 16, the subject matter of any one of Examples 1 to 15, provided that in combination with Example 2, 3, or 7, can optionally include that, the second concentration being substantially more than the first concentration includes that each of the second sublayers includes at least two (e.g., at least three (e.g., exactly three)) atomic layers of the oxide of the second transition metal for each atomic layer of the oxide of the first transition metal.

In Example 17, the subject matter of any one of Examples 1 to 16 can optionally include that, each of the first sublayers substantially consisting of the oxide of the first transition metal includes each of the first sublayers including more than 80 at. % (e.g., more than 80 at. %) of the oxide of the first transition metal.

In Example 18, the subject matter of any one of Examples 1 to 17 can optionally include that, each of the first sublayers substantially consisting of the oxide of the first transition metal includes: each of the first sublayers including the first transition metal and the second transition metal, wherein a concentration of the first transition metal is at least four times a concentration of the second transition metal.

Example 19 is a memory cell including: a first electrode; a second electrode; and a memory element disposed between the first electrode and the second electrode, the first electrode, the second electrode, and the memory element forming a memory capacitor; wherein the memory element includes a spontaneously polarizable memory layer stack, the spontaneously polarizable memory layer stack including an alternating sequence of first sublayers and second sublayers, wherein each of the second sublayers includes (e.g., consists of) an oxide of a first transition metal and an oxide of a second transition metal, wherein each of the first sublayers substantially consists of the oxide of the second transition metal, and wherein each of the second sublayers includes a first concentration of the first transition metal and a second concentration of the second transition metal, wherein the second concentration of the second transition metal is substantially more than the first concentration of the first transition metal.

The memory cell of Example 19 may be configured in accordance with any of the Examples 2, and 4 to 18 if they are applicable.

In Example 20, the subject matter of any one of Examples 1 to 19 can optionally include that the spontaneously polarizable memory layer stack includes a (e.g., overall) concentration of the oxide of the first transition metal equal to or less than 65 at. % (e.g., equal to or less than 60 at. %).

In Example 21, the subject matter of any one of Examples 1 to 20 can optionally include that the oxide of the first transition metal is zirconium oxide and/or wherein the oxide of the second transition metal is hafnium oxide.

In Example 22, the subject matter of any one of Examples 1 to 21 can optionally include that the first electrode and the second electrode consist of the same one or more materials.

In Example 23, the subject matter of any one of Examples 1 to 22 can optionally include that the first electrode and/or the second electrode include/includes tungsten (e.g., tungsten oxide).

In Example 24, the subject matter of any one of Examples 1 to 23 can optionally include that each of the first sublayers has a respective thickness equal to or less than 6 Å.

In Example 25, the subject matter of any one of Examples 1 to 24 can optionally include that each of the second sublayers has a respective thickness equal to or less than 9 Å (e.g., equal to or less than 8 Å).

In Example 26, the subject matter of any one of Examples 1 to 25 can optionally include that each of the second sublayers has the same thickness.

In Example 27, the subject matter of any one of Examples 1 to 26 can optionally include that each of the first sublayers has the same thickness.

Example 28 is a method for processing a memory capacitor, the method including: forming a first electrode layer; forming a spontaneously polarizable memory layer stack over the first electrode layer, wherein forming the spontaneously polarizable memory layer stack includes forming an alternating sequence of first sublayers and second sublayers starting with one of the first sublayers and ending with another one of the first sublayers, wherein each of the second sublayers includes (e.g., substantially consists of) an oxide of a first transition metal and an oxide of a second transition metal and wherein each of the first sublayers substantially consists of the oxide of the first transition metal or the oxide of the second transition metal; and forming a second electrode layer over the spontaneously polarizable memory layer stack.

Example 29 is a method for processing a memory capacitor, the method including: forming a first electrode layer; forming a spontaneously polarizable memory layer stack over the first electrode layer by forming an alternating sequence of first sublayers and second sublayers, wherein each of the second sublayers includes (e.g., consists of) an oxide of a first transition metal and an oxide of a second transition metal, wherein each of the first sublayers substantially consists of the oxide of the first transition metal or the oxide of the second transition metal, and wherein each of the second sublayers includes a first concentration of the first transition metal and a second concentration of the second transition metal which is substantially different from (e.g., more than or less than) the first concentration of the first transition metal; and forming a second electrode layer over the spontaneously polarizable memory layer stack.

In Example 30, the subject matter of Example 28 or 29 can optionally include that forming a respective first sublayer of the first sublayers includes: one or more cycles of atomic layer deposition, wherein each of the one or more cycles includes a precursor pulse of the first transition metal and a pulse of an oxidizer to oxidize the first transition metal, thereby forming the oxide of the first transition metal.

In Example 31, the subject matter of any one of Examples 28 to 30 can optionally include that forming a respective second sublayer of the second sublayers includes: one or more cycles of atomic layer deposition, wherein each of the one or more cycles includes: a first precursor pulse of the first transition metal and a second precursor pulse of the second transition metal, and a pulse of an oxidizer to oxidize the first transition metal and the second transition metal, thereby forming the oxide of the first transition metal and the oxide of the second transition metal.

In Example 32, the subject matter of any one of Examples 28 to 31 can optionally include that forming a respective second sublayer of the second sublayers includes: one or more cycles of atomic layer deposition, wherein each of the one or more cycles includes: at least two sub-cycles (e.g., at least three sub-cycles (e.g., exactly three sub-cycles)), wherein each of the at least two sub-cycles includes a precursor pulse of the second transition metal and a pulse of an oxidizer to oxidize the second transition metal, thereby forming the oxide of the second transition metal; a precursor pulse of the first transition metal; and a pulse of an (e.g., the) oxidizer to oxidize the first transition metal, thereby forming the oxide of the first transition metal.

In Example 33, the subject matter of any one of Examples 28 to 32 can optionally include that forming a respective second sublayer of the second sublayers includes: one or more cycles of atomic layer deposition, wherein each of the one or more cycles includes: one or more first sub-cycles, wherein each of the one or more first sub-cycles includes a precursor pulse of the first transition metal, a precursor pulse of the second transition metal, and a pulse of an oxidizer to oxidize the first transition metal and the second transition metal, thereby forming the oxide of the first transition metal and the oxide of the second transition metal; and one or more second sub-cycles, wherein each of the one or more second sub-cycles includes a precursor pulse of the second transition metal and a pulse of an (e.g., the) oxidizer to oxidize the second transition metal, thereby forming the oxide of the second transition metal. The order of the first and second sub-cycles may be varied. For example, at least one of the first sub-cycles may be carried out between two second sub-cycles, or vice versa.

In Example 34, the method of any one of Examples 30 to 33 can optionally further include a respective purging between two consecutive precursor pulses in the case that the consecutive precursor pulses are carried out in a same process chamber.

In Example 35, the subject matter of any one of Examples 28 to 34 can optionally include that forming a respective first sublayer of the first sublayers includes an atomic layer deposition of the oxide of the first transition metal.

Example 36 is a memory cell including: a first electrode; a second electrode; and a memory element disposed between the first electrode and the second electrode, the first electrode, the second electrode, and the memory element forming a memory capacitor; wherein the memory element includes a spontaneously polarizable memory layer stack, the spontaneously polarizable memory layer stack including an alternating sequence of first sublayers and second sublayers, wherein each of the second sublayers includes an oxide of a first transition metal and an oxide of a second transition metal (e.g., includes a mixed material of the oxide of the first transition metal and the oxide of the second transition metal), wherein each of the first sublayers substantially consists of the oxide of the first transition metal or the oxide of the second transition metal; and (i) wherein each of the second sublayers includes a first concentration of the first transition metal and a second concentration of the second transition metal which is substantially different from the first concentration of the first transition metal (e.g., a first concentration of the first transition metal and a second concentration of the second transition metal in the mixed material may be substantially different from one another), and/or (ii) wherein the alternating sequence of the first sublayers and the second sublayers starts with one of the first sublayers and ends with another one of the first sublayers.

In Example 37, the subject matter of Example 36 can optionally include that the memory element further includes: a first interface sublayer between the first electrode and a closest first sublayer of the first sublayers, wherein the first interface sublayer substantially consists of the oxide of the first transition metal in the case that the closest first sublayer substantially consists of the oxide of the second transition metal or wherein the first interface sublayer substantially consists of the oxide of the second transition metal in the case that the closest first sublayer substantially consists of the oxide of the first transition metal; and a second interface sublayer between the second electrode and a closest first sublayer of the first sublayers, wherein the second interface sublayer substantially consists of the oxide of the first transition metal in the case that the closest first sublayer substantially consists of the oxide of the second transition metal or wherein the second interface sublayer substantially consists of the oxide of the second transition metal in the case that the closest first sublayer substantially consists of the oxide of the first transition metal.

In Example 38, the subject matter of Example 36 can optionally include that the memory element further includes: a first interface sublayer between the first electrode and a closest first sublayer of the first sublayers, wherein the first interface sublayer includes the oxide of the first transition metal and the oxide of the second transition metal; and a second interface sublayer between the second electrode and a closest first sublayer of the first sublayers, wherein the second interface sublayer includes the oxide of the first transition metal and the oxide of the second transition metal.

In Example 39, the subject matter of any one of Examples 36 to 38 can optionally include that every second of the first sublayers substantially consists of the oxide of the first transition metal and wherein every other second of the first sublayers substantially consists of the oxide of the second transition metal.

In Example 40, the subject matter of any one of Examples 36 to 39 can optionally include that the alternating sequence of the first sublayers and the second sublayers starts with one of the first sublayers and ends with another one of the first sublayers; and wherein the one of the first sublayers with which the alternating sequence of first sublayers and second sublayers starts is disposed in direct physical contact with the first electrode and/or wherein the other one of the first sublayers with which the alternating sequence of first sublayers and second sublayers ends is disposed in direct physical contact with the second electrode.

In Example 41, the subject matter of any one of Examples 36 to 40 can optionally include that the alternating sequence of the first sublayers and the second sublayers starts with one of the first sublayers and ends with another one of the first sublayers; and wherein the one of the first sublayers with which the alternating sequence of first sublayers and second sublayers starts and the other one of the first sublayers with which the alternating sequence of first sublayers and second sublayers ends have the same thickness.

In Example 42, the subject matter of any one of Examples 36 to 41 can optionally include that, the second concentration being substantially different from the first concentration includes that the second concentration of the second transition metal is at least 1.5-times the first concentration of the first transition metal or that the first concentration of the first transition metal is at least 1.5-times the second concentration of the second transition metal.

In Example 43, the subject matter of any one of Examples 36 to 42 can optionally include that the second concentration being substantially different from the first concentration includes that either a concentration of the oxide of the first transition metal or a concentration of the oxide of the second transition metal within each of the second sublayers is equal to or greater than 70 at. %.

In Example 44, the subject matter of any one of Examples 36 to 43 can optionally include that the second concentration of each of the second sublayers being substantially different from the first concentration includes that the second sublayers include on average either a concentration of the oxide of the first transition metal of equal to or greater than 60 at. % or a concentration of the oxide of the second transition metal of equal to or greater than 60 at. %.

In Example 45, the subject matter of any one of Examples 36 to 44 can optionally include that, in the case that a respective first sublayer of the first sublayers substantially consists of the oxide of the first transition metal, the respective first sublayer includes more than 90 at. % of the oxide of the first transition metal; and/or wherein, in the case that a respective first sublayer of the first sublayers substantially consists of the oxide of the second transition metal, the respective first sublayer includes more than 90 at. % of the oxide of the second transition metal.

In Example 46, the subject matter of any one of Examples 36 to 45 can optionally include that, in the case that a respective first sublayer of the first sublayers substantially consists of the oxide of the first transition metal, the respective first sublayer includes the first transition metal and a metal impurity, wherein a concentration of the first transition metal is at least four times the concentration of the metal impurity (such that an atomic ratio between the first transition metal and the metal impurity is at least four to one); and/or wherein, in the case that a respective first sublayer of the first sublayers substantially consists of the oxide of the second transition metal, the respective first sublayer includes the second transition metal and a metal impurity, wherein a concentration of the second transition metal is at least four times the concentration of the metal impurity (such that an atomic ratio between the second transition metal and the metal impurity is at least four to one).

In Example 47, the subject matter of any one of Examples 36 to 46 can optionally include that, in the case that each of the first sublayers substantially consists of the oxide of the first transition metal, the spontaneously polarizable memory layer stack includes an overall concentration of the oxide of the first transition metal equal to or less than 65 at. %; wherein, in the case that each of the first sublayers substantially consists of the oxide of the second transition metal, the spontaneously polarizable memory layer stack includes an overall concentration of the oxide of the second transition metal equal to or less than 65 at. %.

In Example 48, the subject matter of any one of Examples 36 to 362 can optionally include that the first transition metal is zirconium and wherein the second transition metal is hafnium; or wherein the first transition metal is hafnium and wherein the second transition metal is zirconium.

In Example 49, the subject matter of any one of Examples 36 to 48 can optionally include that the first electrode and the second electrode consist of the same one or more materials.

In Example 50, the subject matter of any one of Examples 36 to 49 can optionally include that the first electrode and/or the second electrode include tungsten.

In Example 51, the subject matter of any one of Examples 36 to 50 can optionally include that each of the first sublayers has a respective thickness different from a respective thickness of each of the second sublayers.

In Example 52, the subject matter of any one of Examples 36 to 51 can optionally include that each of the second sublayers has the same thickness; and/or wherein each of the first sublayers has the same thickness.

Example 53 is a memory cell including: a first electrode; a second electrode; and a memory element disposed between the first electrode and the second electrode, the first electrode, the second electrode, and the memory element forming a memory capacitor; wherein the memory element includes a first interface sublayer in direct physical contact with the first electrode, a second interface sublayer in direct physical contact with the second electrode, and a spontaneously polarizable memory layer stack disposed between the first interface sublayer and the second interface sublayer, wherein the spontaneously polarizable memory layer stack includes an alternating sequence of first sublayers and second sublayers, wherein each of the second sublayers includes an oxide of a first transition metal and an oxide of a second transition metal, wherein each of the first sublayers substantially consists of the oxide of the first transition metal or the oxide of the second transition metal; and wherein each of the second sublayers includes a first concentration of the first transition metal and a second concentration of the second transition metal which is substantially different from the first concentration of the first transition metal, and wherein the alternating sequence of the first sublayers and the second sublayers starts with one of the first sublayers and ends with another one of the first sublayers.

Example 54 is a method for processing a memory capacitor, the method including: forming a first electrode layer; forming a spontaneously polarizable memory layer stack over the first electrode layer, wherein forming the spontaneously polarizable memory layer stack includes forming an alternating sequence of first sublayers and second sublayers starting with one of the first sublayers and ending with another one of the first sublayers, wherein each of the second sublayers includes an oxide of a first transition metal and an oxide of a second transition metal and wherein each of the first sublayers substantially consists of the oxide of the first transition metal or the oxide of the second transition metal; and forming a second electrode layer over the spontaneously polarizable memory layer stack.

In Example 55, the subject matter of Example 54 can optionally include that forming a respective second sublayer of the second sublayers includes: one or more cycles of atomic layer deposition, wherein each of the one or more cycles includes: one or more first sub-cycles, wherein each of the one or more first sub-cycles includes a precursor pulse of the first transition metal, a precursor pulse of the second transition metal, and a pulse of an oxidizer to oxidize the first transition metal and the second transition metal, thereby forming the oxide of the first transition metal and the oxide of the second transition metal; and one or more second sub-cycles, wherein each of the one or more second sub-cycles includes a precursor pulse of the second transition metal and a pulse of an (e.g., the) oxidizer to oxidize the second transition metal, thereby forming the oxide of the second transition metal.

It is understood that any one of Examples 36 to 55 may be combined with any one of Examples 1 to 35 if applicable.

Several aspects are described with reference to a structure (e.g., a memory transistor structure, e.g., a field-effect transistor structure, e.g., a ferroelectric field-effect transistor structure, e.g., a capacitive memory structure) and it is noted that such a structure may include solely the respective element (e.g., a memory transistor, e.g., a field-effect transistor, e.g., a ferroelectric field-effect transistor, e.g., a capacitive memory); or, in other aspects, a structure may include the respective element and one or more additional elements.

In some aspects, two voltages may be compared with one another by relative terms such as “greater”, “higher”, “lower”, “less”, or “equal”, for example. It is understood that, in some aspects, a comparison may include the sign (positive or negative) of the voltage value or, in other aspects, the absolute voltage values (also referred to as the magnitude, or as the amplitude, e.g., of a voltage pulse) are considered for the comparison.

The term “switch” may be used herein to describe a modification of the memory state a memory cell is residing in. For example, in the case that a memory cell is residing in a first memory state (e.g., the LVT state), the memory state the memory cell is residing in may be switched such that, after the switch, the memory cell may reside in a second memory state (e.g., the HVT state), different from the first memory state. The term “switch” may thus be used herein to describe a modification of the memory state a memory cell is residing in, from a first memory state to a second memory state. The term “switch” may also be used herein to describe a modification of a polarization, for example of a spontaneously-polarizable memory element (e.g., of a spontaneously-polarizable layer, such as a remanent-polarizable layer). For example, a polarization of a spontaneously-polarizable memory element may be switched, such that the sign of the polarization varies from positive to negative or from negative to positive, while the absolute value of the polarization may remain in some aspects substantially unaltered. According to various aspects, writing a memory cell may include bringing the memory cell from one of at least two memory states into another one of the at least two memory states of the memory cell (e.g., from the LVT state into the HVT state, or vice versa).

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “coupled to” used herein with reference to functional parts of a memory cell (e.g., functional parts of a memory structure) that are coupled to respective nodes (e.g., source-line node, bit-line node, and/or word-line node) of the memory cell may be understood as follows: the respective functional parts are electrically conductively connected to corresponding nodes and/or the respective functional parts itself provide the corresponding nodes. As an example, a source/drain node of a field-effect transistor memory structure may be electrically conductively connected to the source-line node of the memory cell or the source/drain node of the field-effect transistor memory structure may provide the source-line node of the memory cell. As another example, a source/drain node of the field-effect transistor memory structure may be electrically conductively connected to the bit-line node of the memory cell or the source/drain node of the field-effect transistor memory structure may provide the bit-line node of the memory cell.

The term “metal” or “metal material” may be used herein to describe a metal (e.g., a pure or substantially pure metal), a mixture of more than one metal, a metal alloy, an intermetallic material, a conductive metal compound (e.g., a nitride), and the like. Illustratively, the term “metal” may be used herein to describe a material having an electrical conductivity typical of a metal, for example an electrical conductivity greater than 10⁶ S/m at a temperature of 20° C. The term “metal material” may be used herein to describe a material having the Fermi level inside at least one band.

The terms “electrically conducting” or “electrically conductive” may be used herein interchangeably to describe a material or a layer having an electrical conductivity or an average electrical conductivity greater than 10⁶ S/m at a temperature of 20° C. The term “electrically insulating” may be used herein interchangeably to describe a material or a layer having an electrical conductivity or an average electrical conductivity less than 10⁻¹⁰ S/m at a temperature of 20° C. In some aspects, a difference in electrical conductivity between an electrically conducting material (or layer) and an electrically insulating material (or layer) may have an absolute value of at least 10¹⁰ S/m at a temperature of 20° C., or of at least 10¹⁵ S/m at a temperature of 20° C.

The term “content” may be used herein, in some aspects, in relation to the “content of an element” in a material or in a layer to describe the mass percentage (or fraction) of that element over a total mass of the material (or of the layer). The term “content” may be used herein in relation to the “content of defects” in the structure of a material to describe the mass percentage of the defects over a total mass of the constituents of the structure. The term “content” may be used herein, in some aspects, in relation to the “content of an element” in a material or in a layer to describe the volume percentage of that element over a total volume of the material (or of the layer). The term “content” may be used herein in relation to the “content of defects” in the structure of a material to describe the volume percentage of the defects over a total volume of the structure.

The expression “a material of an element” or “a material of a layer”, for example “a material of a memory element”, or “a material of an electrode layer” may be used herein to describe a main component of that element or layer, e.g., a main material (for example, a main element or a main compound) present in that element or layer. The expression “a material of an element” or “a material of a layer” may describe, in some aspects, the material of that element or layer having a weight percentage greater than 60% over the total weight of the materials that the element or layer includes. The expression “a material of an element” or “a material of a layer” may describe, in some aspects, the material of that element or layer having a volume percentage greater than 60% over the total volume of the materials that the element or layer includes. As an example, a material of an element or layer including aluminum may describe that that element or layer is formed mostly by aluminum, and that other elements (e.g., impurities) may be present in a smaller proportion, e.g., having less weight percentage or less volume percentage compared to aluminum. As another example, a material of an element or layer including titanium nitride may describe that that element or layer is formed mostly by titanium nitride, and that other elements (e.g., impurities) may be present in a smaller proportion, e.g., having less weight percentage or less volume percentage compared to titanium nitride.

The term “region” used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.,). In some aspects, the continuous region of a semiconductor portion may be provided by semiconductor material having only one dominant doping type.

The word “over”, used herein to describe forming a feature, e.g., a layer “over” a side or surface, may be used to mean that the feature, e.g., the layer, may be formed “directly on”, e.g., in direct contact with, the implied side or surface. The word “over”, used herein to describe forming a feature, e.g., a layer “over” a side or surface, may be used to mean that the feature, e.g., the layer, may be formed “indirectly on” the implied side or surface with one or more additional layers being arranged between the implied side or surface and the formed layer.

The term “lateral” used with regards to a lateral dimension (in other words a lateral extent) of a structure, a portion, a structure element, a layer, etc., provided, for example, over and/or in a carrier (e.g., a layer, a substrate, a wafer, etc.) or “laterally” next to, may be used herein to mean an extent or a positional relationship along a surface of the carrier. That means, in some aspects, that a surface of a carrier (e.g., a surface of a layer, a surface of a substrate, a surface of a wafer, etc.) may serve as reference, commonly referred to as the main processing surface. Further, the term “width” used with regards to a “width” of a structure, a portion, a structure element, a layer, etc., may be used herein to mean the lateral dimension (or in other words the lateral extent) of a structure. Further, the term “height” used with regards to a height of a structure, a portion, a structure element, a layer, etc., may be used herein to mean a dimension (in other words an extent) of a structure in a direction perpendicular to the surface of a carrier (e.g., perpendicular to the main processing surface of a carrier).

The term “thickness” used with regards to a “thickness” of a layer may be used herein to mean the dimension (in other words an extent) of the layer perpendicular to the surface of the support (the material or material structure) on which the layer is formed (e.g., deposited or grown). If a surface of the support is parallel to the surface of the carrier (e.g., parallel to the main processing surface) the “thickness” of the layer formed on the surface of the support may be the same as the height of the layer.

According to various aspects, various properties (e.g., physical properties, chemical properties, etc.) of a first component (e.g., elements, layers, structures, portions, etc.) and a second component may be compared to one another. It may be found that two or more components may be—with reference to a specific property—either equal to each other or different from one another. As a measure, a value that represents such a property may be either equal or not. In general, a skilled person may understand from the context of the application whether two values or properties are equal or not, e.g., usually, if values are in the range of a usual tolerance, they may be regarded equal. However, in some aspects or as long as not otherwise mentioned or understood, two values that differ from one another with at least 1% relative difference may be considered different from one another. Accordingly, two values that differ from one another with less than 1% relative difference may be considered equal to each other.

It may be understood, that the physical term “electrical conductivity” (also referred to as specific conductance, specific electrical conductance, as examples) may be defined as a material dependent property reciprocal to the physical term “electrical resistivity” (also referred to as specific electrical resistance, volume resistivity, as examples). Further properties of a layer or structure may be defined material dependent and the geometry dependent, e.g., by the physical terms “electrical resistance” and “electrical conductance”.

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

According to various aspects, the properties and/or the structure of the memory element, an electrode, an electrically conductive electrode layer, and/or a functional layer as described herein may be evaluated with techniques known in the art. As an example, transmission electron microscopy (TEM) may be used to determine the structure of an electrode, for example the presence of one or more electrode layers and/or the presence of one or more functional layers in the electrode. TEM may be used for identifying a layer, an interface, a crystal structure, a microstructure, and other properties. As another example, X-ray crystallography (X-ray diffraction) may be used to determine various properties of a layer or a material, such as the crystal structure, the lattice properties, the size and shape of a unit cell, the chemical composition, the phase or alteration of the phase, the presence of stress in the crystal structure, the microstructure, and the like. As a further example, energy-dispersive X-ray spectroscopy (EDS) may be used to determine the chemical composition of a layer or a material, e.g. the presence and/or the content of an element in the layer or material. As a further example, Rutherford backscattering spectrometry (RBS) may be used to determine the structure and/or the composition of a material. As a further example, secondary ion mass spectrometry (SIMS) may be used to analyze the molecular composition of the upper monolayers of a solid, e.g. for analyzing the spatial distribution (e.g., the gradient) of an element across the solid.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory cell, comprising:
a first electrode;
a second electrode; and
a memory element disposed between the first electrode and the second electrode, the first electrode, the second electrode, and the memory element forming a memory capacitor;
wherein the memory element comprises a spontaneously polarizable memory layer stack, the spontaneously polarizable memory layer stack comprising an alternating sequence of first sublayers and second sublayers, wherein each of the second sublayers substantially consists of a mixed material of an oxide of a first transition metal and an oxide of a second transition metal, wherein each of the first sublayers substantially consists of the oxide of the first transition metal or the oxide of the second transition metal; and
(i) wherein a first concentration of the first transition metal and a second concentration of the second transition metal in the mixed material are substantially different from one another, and/or
(ii) wherein the alternating sequence of the first sublayers and the second sublayers starts with one of the first sublayers and ends with another one of the first sublayers.

2. The memory cell according to claim 1,
wherein the memory element further comprises:
a first interface sublayer between the first electrode and the spontaneously polarizable memory layer stack, wherein the first interface sublayer substantially consists of the oxide of the first transition metal in the case that one of the first sublayers that is closest to the first interface sublayer substantially consists of the oxide of the second transition metal or wherein the first interface sublayer substantially consists of the oxide of the second transition metal in the case that one of the first sublayers that is closest to the first interface sublayer substantially consists of the oxide of the first transition metal; and
a second interface sublayer between the second electrode and the spontaneously polarizable memory layer stack, wherein the second interface sublayer substantially consists of the oxide of the first transition metal in the case that one of the first sublayers that is closest to the second interface sublayer substantially consists of the oxide of the second transition metal or wherein the second interface sublayer substantially consists of the oxide of the second transition metal in the case that one of the first sublayers that is closest to the second interface sublayer substantially consists of the oxide of the first transition metal.

3. The memory cell according to claim 1,
wherein the memory element further comprises:
a first interface sublayer between the first electrode and the spontaneously polarizable memory layer stack, wherein the first interface sublayer comprises a mixed material of the oxide of the first transition metal and the oxide of the second transition metal; and
a second interface sublayer between the second electrode and the spontaneously polarizable memory layer stack, wherein the second interface sublayer comprises a mixed material of the oxide of the first transition metal and the oxide of the second transition metal.

4. The memory cell according to claim 1,
wherein one of the first sublayers substantially consists of the oxide of the first transition metal and wherein another one of the first sublayers substantially consists of the oxide of the second transition metal.

5. The memory cell according to claim 1,
wherein the alternating sequence of the first sublayers and the second sublayers starts with one of the first sublayers and ends with another one of the first sublayers; and
wherein the one of the first sublayers with which the alternating sequence of first sublayers and second sublayers starts is disposed in direct physical contact with the first electrode and/or wherein the other one of the first sublayers with which the alternating sequence of first sublayers and second sublayers ends is disposed in direct physical contact with the second electrode.

6. The memory cell according to claim 1,
wherein the alternating sequence of the first sublayers and the second sublayers starts with one of the first sublayers and ends with another one of the first sublayers; and
wherein the one of the first sublayers with which the alternating sequence of first sublayers and second sublayers starts and the other one of the first sublayers with which the alternating sequence of first sublayers and second sublayers ends have the same thickness.

7. The memory cell according to claim 1,
wherein in the mixed material the second concentration of the second transition metal is at least 1.5-times the first concentration of the first transition metal or wherein in the mixed material the first concentration of the first transition metal is at least 1.5-times the second concentration of the second transition metal.

8. The memory cell according to claim 1,
wherein either a first concentration of the oxide of the first transition metal or a second concentration of the oxide of the second transition metal in the mixed material is greater than 70 at. %.

9. The memory cell according to claim 1,
wherein in the mixed material either a concentration of the oxide of the first transition metal is greater than 60 at. % or a concentration of the oxide of the second transition metal is greater than 60 at. %.

10. The memory cell according to claim 1,
wherein, in the case that a respective first sublayer of the first sublayers substantially consists of the oxide of the first transition metal, the respective first sublayer comprises more than 90 at. % of the oxide of the first transition metal; and/or
wherein, in the case that a respective first sublayer of the first sublayers substantially consists of the oxide of the second transition metal, the respective first sublayer comprises more than 90 at. % of the oxide of the second transition metal.

11. The memory cell according to claim 1,
wherein, in the case that a respective first sublayer of the first sublayers substantially consists of the oxide of the first transition metal, the respective first sublayer comprises the first transition metal and a metal impurity, wherein a concentration of the first transition metal is at least four times the concentration of the metal impurity; and/or
wherein, in the case that a respective first sublayer of the first sublayers substantially consists of the oxide of the second transition metal, the respective first sublayer comprises the second transition metal and a metal impurity, wherein a concentration of the second transition metal is at least four times the concentration of the metal impurity.

12. The memory cell according to claim 1,
wherein, in the case that each of the first sublayers substantially consists of the oxide of the first transition metal, the spontaneously polarizable memory layer stack comprises an overall concentration of the oxide of the first transition metal equal to or less than 65 at. %; and
wherein, in the case that each of the first sublayers substantially consists of the oxide of the second transition metal, the spontaneously polarizable memory layer stack comprises an overall concentration of the oxide of the second transition metal equal to or less than 65 at. %.

13. The memory cell according to claim 1,
wherein the first transition metal is zirconium and wherein the second transition metal is hafnium; or
wherein the first transition metal is hafnium and wherein the second transition metal is zirconium.

14. The memory cell according to claim 1,
wherein the first electrode and the second electrode consist of the same one or more materials.

15. The memory cell according to claim 1,
wherein the first electrode and/or the second electrode comprise tungsten.

16. The memory cell according to claim 1,
wherein each of the first sublayers has a respective thickness different from a respective thickness of each of the second sublayers.

17. The memory cell according to claim 1,
wherein each of the second sublayers has the same thickness; and/or
wherein each of the first sublayers has the same thickness.

18. A memory cell, comprising:
a first electrode;
a second electrode; and
a memory element disposed between the first electrode and the second electrode, the first electrode, the second electrode, and the memory element forming a memory capacitor;
wherein the memory element comprises a first interface sublayer in direct physical contact with the first electrode, a second interface sublayer in direct physical contact with the second electrode, and a spontaneously polarizable memory layer stack in contact with both the first interface sublayer and the second interface sublayer, wherein the spontaneously polarizable memory layer stack comprises an alternating sequence of first sublayers and second sublayers, wherein each of the second sublayers substantially consists of a mixed material of an oxide of a first transition metal and an oxide of a second transition metal, wherein each of the first sublayers substantially consists of the oxide of the first transition metal or the oxide of the second transition metal; and
wherein a first concentration of the first transition metal and a second concentration of the second transition metal in the mixed material are substantially different from one another, and wherein the alternating sequence of the first sublayers and the second sublayers starts with one of the first sublayers and ends with another one of the first sublayers.

19. A method for processing a memory capacitor comprising:
forming a first electrode layer;
forming a spontaneously polarizable memory layer stack over the first electrode layer, wherein forming the spontaneously polarizable memory layer stack comprises forming an alternating sequence of first sublayers and second sublayers starting with one of the first sublayers and ending with another one of the first sublayers, wherein each of the second sublayers substantially consists of a mixed material of an oxide of a first transition metal and an oxide of a second transition metal and wherein each of the first sublayers substantially consists of the oxide of the first transition metal or the oxide of the second transition metal; and
forming a second electrode layer over the spontaneously polarizable memory layer stack.

20. The method according to claim 19,
wherein forming a respective second sublayer of the second sublayers comprises:
one or more cycles of atomic layer deposition, wherein each of the one or more cycles comprises:
a first sub-cycle comprising a precursor pulse of the first transition metal and a pulse of an oxidizer to oxidize the first transition metal, thereby forming the oxide of the first transition metal; and
at least two second sub-cycles, wherein each of the at least two second sub-cycles comprises a precursor pulse of the second transition metal and a pulse of an oxidizer to oxidize the second transition metal, thereby forming the oxide of the second transition metal.
